(19) United States
(12) Patent Application Publication
(10) Pub. No.: US 2026/0279254 A1
(43) Pub. Date: Sep. 17, 2026

(54) DISPLAY DEVICE COMPRISING A VARIABLE-WAVELENGTH LED AND METHODS OF CALIBRATING AND DRIVING A DISPLAY DEVICE COMPRISING A VARIABLE-WAVELENGTH

(71) Applicant: PORO TECHNOLOGIES LTD, Cambridge Cambridgeshire (GB)

(72) Inventors: Jen-Wu FANG, Cambridge (GB); Guan-Ru HE, Cambridge (GB)

(73) Assignee: PORO TECHNOLOGIES LTD, Cambridge Cambridgeshire (GB)

(21) Appl. No.: 19/167,682

(22) PCT Filed: Mar. 22, 2024
(86) PCT No.: PCT/GB2024/050792

§ 371 Date: Sep. 22, 2025

(30) Foreign Application Priority Data
Mar. 24, 2023 (GB) 2304364.9

(51) Int. Cl. G09G 3/32; G09G 3/00; H10H 20/812; H10H 29/85; H10H 29/851

(52) U.S. Cl. CPC G09G 3/32; G09G 3/006; H10H 29/8517; G09G 2320/0233; G09G 2320/0693; G09G 2330/12; H10H 20/812; H10H 29/8512

(57) ABSTRACT

A display device comprises a variable-wavelength LED, the variable-wavelength LED being a pixel of the device, or one of a plurality of subpixels of a device pixel, and an absorptive colour filter. The absorptive colour filter is positioned between the variable-wavelength LED and an outlet of the display device, such that light emitted by the variable-wavelength LED passes through the absorptive colour filter before passing out of the outlet of the display device. The variable-wavelength LED, or a second LED subpixel, is driveable to emit light at a first emission wavelength in response to a first electrical driving condition, and the variable-wavelength LED is driveable to emit light at a second emission wavelength in response to a second electrical driving condition. The absorptive colour filter is configured to attenuate the luminance of light emitted at the second emission wavelength, which is shorter than the first emission wavelength. Methods of calibrating and driving the display device are also provided.

The present invention relates to a display device comprising a variable-wavelength LED, a method of calibrating a display device comprising a variable-wavelength LED, and a method of driving a display device comprising a variable-wavelength LED. In particular, the invention relates to a display device comprising a variable-wavelength LED and an absorptive colour filter.

### BACKGROUND

III-V semiconductor materials are of particular interest for semiconductor device design, in particular the family of III-nitride semiconductor materials.

“III-V” semiconductors include binary, ternary and quaternary alloys of Group III elements, such as Ga, Al and In, with Group V elements, such as N, P, As and Sb, and are of great interest for a number of applications, including electronics and optoelectronics.

Of particular interest is the class of semiconductor materials known as “III-nitride” materials, which includes gallium nitride (GaN), indium nitride (InN) and aluminium nitride (AlN), along with their ternary and quaternary alloys. (Al,In)GaN is a term encompassing AlGaN, InGaN and GaN. III-nitride materials have not only achieved commercial success in solid-state lighting and power electronics, but also exhibit particular advantages for quantum light sources and light-matter interaction.

While a variety of III-nitride materials are commercially interesting, Gallium nitride (GaN) is widely regarded as one of the most important new semiconductor materials, and is of particular interest for a number of applications.

The present invention will be described primarily by reference to GaN and InGaN, but may advantageously be applicable to alternative III-nitride material combinations.

It is known that the introduction of pores into bulk III-nitrides, such as GaN can profoundly affect its material properties (optical, mechanical, electrical, and thermal, etc.). The possibility of tuning a wide range of material properties of GaN and III-nitride semiconductors by altering its porosity therefore makes porous GaN of great interest for optoelectronic applications.

In a significant improvement over conventional three-colour LED displays, Poro Technologies Ltd, the present applicant, has developed variable-wavelength LEDs formed from III-nitride semiconductor materials grown over a porous region of III-nitride material. Instead of a conventional LED which emits at a single colour, these variable-wavelength LEDs can emit a broad spectrum of different emission wavelengths in response to varying the driving conditions provided to the variable-wavelength LED. These variable-wavelength LEDs, and their method of manufacture, are set out below.

As the peak emission-wavelength of such variable-wavelength LEDs can be tuned by varying the driving conditions, a single variable-wavelength LED can take the place of multiple “single-colour” subpixels. In particularly preferred embodiments, the same variable-wavelength LED can be tuned to emit any one of red, green or blue light by tuning the driving conditions provided to that LED. This means that a colour display can be formed from an array of variable-wavelength LEDs, with each variable-wavelength LED acting as a colour-variable pixel, or alternatively as a colour-variable subpixel in a subpixellated display.

The ability of variable-wavelength LEDs to emit such a broad range of emission wavelengths makes display driving and calibration processes significantly more complex than it would be for a conventional RGB subpixel display. The peak emission wavelength of the variable-wavelength LEDs is strongly dependent on the magnitude of the electrical driving signal provided to a given LED, and longer-wavelength emission colours require lower-magnitude driving currents/voltages which inherently produce a lower luminance. This presents a challenge, as white balance must be maintained between primary emission wavelengths with inherently different luminances. Additional challenges are presented by the inherent limitations on how short the driving duty cycle can be made for shorter, brighter emission wavelengths.

### SUMMARY OF INVENTION

The present application relates to a display device comprising a variable-wavelength light emitting diode (LED), a method of calibrating a display device comprising a variable-wavelength light emitting diode (LED), and a method of driving a display device comprising a variable-wavelength light emitting diode (LED). The display device may preferably comprise a plurality of such variable-wavelength LEDs, for example an array of variable-wavelength microLEDs.

The invention is defined in the independent claims, to which reference should now be made. Preferred or advantageous features of the invention are defined in the appended sub-claims.

### Display Device

In a first aspect of the present invention there is provided a display device comprising: a variable-wavelength LED, the variable-wavelength LED being a pixel of the device, or one of a plurality of subpixels of a device pixel; and an absorptive colour filter. The absorptive colour filter is positioned between the variable-wavelength LED and an outlet of the display device, such that light emitted by the variable-wavelength LED passes through the absorptive colour filter before passing out of the outlet of the display device.

The variable-wavelength LED, or a second LED subpixel, is driveable to emit light at a first emission wavelength in response to a first electrical driving condition provided to the variable-wavelength LED or the second LED subpixel. The variable-wavelength LED is driveable to emit light at a second emission wavelength in response to a second electrical driving condition.

Preferably the variable-wavelength LED is driveable to emit light at the first emission wavelength in response to the first electrical driving condition, and to emit light at a second emission wavelength in response to a second electrical driving condition. The first and second emission wavelengths are preferably both within an emission wavelength range of the variable-wavelength LED.

The second emission wavelength is preferably shorter than the first emission wavelength, and the absorptive colour filter is configured to attenuate the luminance of light emitted at the second emission wavelength.

As the first emission wavelength has a longer wavelength than the second primary emission wavelength, if the duty cycles of the first and second driving conditions are equal, then due to the correlation of brightness and driving current density, the first wavelength is emitted in use with a first luminance that is lower than a second luminance with which the second primary emission wavelength is emitted. The absorptive filter compensates for this difference in the luminosities of different emission wavelengths by absorbing some of the light emitted at the second emission wavelength.

The absorptive colour filter is a wavelength-selective filter, such that the absorptive colour filter absorbs light with certain wavelengths, while allowing light with other wavelengths to be transmitted through the filter without being absorbed.

The absorptive colour filter may be configured to attenuate the luminance of light within an absorption wavelength range. Absorptive colour filters may be designed to absorb light at particular wavelengths, as is known in the art of photography and optical instruments, for example.

The display device according to the present invention may comprise an absorptive colour filter which is configured to absorb a proportion of the intensity of light emitted by the variable-wavelength LED at the second emission wavelength. Thus the absorptive colour filter may be configured to partially block the transmission of light at, or having, the second emission wavelength. In practice the filter may be configured to partially block the transmission of light within an absorption wavelength range of the filter, the absorption wavelength range of the filter containing the second emission wavelength.

An example of variable-wavelength LEDs usable in the present invention are known as dynamic-pixel-tuning (DPT®) variable-wavelength LEDs from Poro Technologies Ltd, and are disclosed in international patent application no. PCT/GB2022/051997, published as WO2023/007174.

Although a continuum of different emission wavelengths can be emitted directly from a variable-wavelength LED by varying the driving conditions supplied to that LED, additional chromaticities may be displayed by driving the LED to emit a plurality of “primary” wavelengths, such that the overall output signal observed by a viewer is a temporal combination of the emitted primaries.

In a subpixellated display, different primary emission wavelengths can be emitted by separate subpixels. The subpixels may all be variable-wavelength LEDs, or some subpixels may be non-variable-wavelength LEDs.

In one preferred embodiment, the display device is a subpixellated display, in which the variable-wavelength LED is a first subpixel which is driveable to emit light at the second emission wavelength in response to the second driving condition being provided to the first subpixel, and in which the display comprises a second LED subpixel which is driveable to emit light at the first emission wavelength in response to the first driving condition being provided to the first subpixel. The second LED subpixel is preferably a second variable-wavelength LED subpixel. In this embodiment the first and second subpixels are subpixels of a display pixel, and the first and second subpixels are driveable independently of one another.

In subpixellated embodiments of the display device, due to the proximity of the subpixels to one another, the light emitted by the subpixels at the first and second primary emission wavelengths combines to form an output signal with an output chromaticity and output luminance L_{O}. A viewer observing the display device will perceive only a single output signal from the subpixellated pixel within the display frame, and that perceived output signal will have a single output chromaticity and luminance which are the temporal average of the emission wavelengths emitted field-sequentially by the variable-wavelength LED subpixels.

In another preferred embodiment, the variable-wavelength LED is a pixel of the device, and the display device is a field-sequential display. In this embodiment, the same variable-wavelength LED pixel is driven to emit a plurality of discrete emission wavelengths by driving the LED pixel with a plurality of different driving conditions. The variable-wavelength LED is driveable to emit light at the first emission wavelength in response to the first electrical driving condition provided to the variable-wavelength LED, and the variable-wavelength LED is driveable to emit light at the second emission wavelength in response to a second electrical driving condition provided to the variable-wavelength LED.

In a sequential-field display, the same variable-wavelength LED may be controlled to emit multiple emission wavelengths, by supplying different driving conditions to the LED in sequential subframes of a display frame. In this way, the same variable-wavelength LED may be a pixel that emits a plurality of selected “primary emission wavelengths” one after another within the duration of a single display frame.

In use, the variable-wavelength LED of the display device is preferably driven to emit light at both the first emission wavelength and the second emission wavelength in turn, by varying the driving condition provided to the variable-wavelength LED.

The display device is preferably driven with field-sequential control, so that the first and second emission wavelengths are emitted by the same variable-wavelength LED during discrete display subframes within a single display frame. In other words, the same LED emits the first and second emission wavelengths one after another, during a short space of time (a display frame). The light emitted at the first and second primary emission wavelengths combines to form an output signal with an output chromaticity and output luminance L_{O}. A viewer observing the display device will perceive only a single output signal from the variable-wavelength LED within the display frame, and that perceived output signal will have a single output chromaticity and luminance which are the temporal average of the emission wavelengths emitted field-sequentially by the variable-wavelength LED.

A particular feature of the dynamic-pixel-tuning (DPT®) variable-wavelength LEDs designed by Poro Technologies Ltd and described at international patent application no.

PCT/GB2022/051997, published as WO2023/007174, is that the emission wavelength of the variable-wavelength LED is determined by the driving condition, for example the driving current density, provided to the LED. The luminance, or brightness, with which that wavelength is emitted is determined by the duty cycle of the driving condition (the length of time over which the driving condition is supplied to the variable-wavelength LED).

The luminances of emitted wavelengths are therefore controlled by pulse width modulation (PWM) of the driving signal, i.e. controlling the width of the pulses of driving current density which are provided to the variable-wavelength LED.

If pulses of light at different emission wavelengths are to be combined to create a perceived output signal with a desired output chromaticity and output luminance, both the chromaticities of the individual pulses, and the luminances of the individual pulses, are interlinked. For example if the output signal is to be made brighter without changing the output chromaticity, it is necessary to increase the luminances of all of the individual emitted pulses making up the output signal. This is done by increasing the length of the pulses of respective driving conditions, while maintaining the relative ratio between the duty cycles of the pulse-width-modulated pulses. If the luminance of one emitted wavelength is changed more than the others and departs from the desired colour-balance-ratio, the perceived colour- and brightness-balance of the display will be negatively affected. Such displays therefore face brightness limitations when the duty cycle of any given primary emission colour reaches 100%. At that point, the duty cycle for that emission wavelength cannot be made any longer, so the luminance of that given emission wavelength cannot be increased further. This limits the overall brightness of the display, as in order to maintain colour-balance the other emission wavelengths also cannot be made any brighter after this point.

For dynamic-pixel-tuning (DPT®) variable-wavelength LEDs, longer-wavelength emission colours require lower-magnitude driving currents/voltages which inherently produce a lower luminance. The low current density required to drive the variable-wavelength LED to emit red light, for example, means that the luminance of red emission is inherently low—this can be a limiting factor as the duty cycle of the red driving condition cannot be increased beyond 100%.

In one preferred embodiment, a set of two primaries (primary emission wavelengths and their associated driving conditions) may be selected to be used for display control. The output signal produced by the variable-wavelength LED then has an output chromaticity and output luminance L_{O} determined by the temporal combination of the first and second primary emission wavelengths and their associated luminances.

In a preferred embodiment, a set of three primaries (primary emission wavelengths and their associated subfields of driving conditions) may be selected: the first primary emission wavelength, the second primary emission wavelength, and a third primary emission wavelength.

In an exemplary embodiment, a set of three primaries is selected for use in a given display frame. In order to achieve a wide displayable colour gamut, the three primaries may be selected to be nominally red (R), green (G) and blue (B).

In one example embodiment, red, green and blue primary emission wavelengths may be selected to be 639 nm, 533 nm and 466 nm respectively.

Even though the variable-wavelength LED may be driveable to emit all of the primary wavelengths, a white-balance condition is selected so that the relative luminances of the three primary emission wavelengths can be set. The driving conditions for the display device may then be calibrated so that the variable-wavelength LED can be controlled to emit a “white” output signal on command.

The primary emission wavelengths and their driving conditions may be set so that the combined wavelengths and luminances of the primaries are complementary and sum to a standard illuminant white point, such as CIE standard illuminant point D65.

In order to make a D65 white output signal using the three primary wavelengths of 639 nm, 533 nm and 466 nm, the luminances of the red/green/blue primaries must be set in the ratio 1.6:3.6:1 respectively.

The low current density required to drive the variable-wavelength LED to emit red light at 639 nm means that the luminance of the red primary is naturally the lowest of the three primaries. The low brightness of the longest-wavelength of the selected primary emission wavelengths (the red primary in this example) is therefore a limiting factor in the overall brightness of the output signal.

In order to maximise the luminance of the red primary, the duty cycle of the red driving condition may be set to 100% duty cycle.

In order to meet the required white-balance ratio of 1.6:3.6:1, the duty cycles of the green and blue driving conditions must be reduced until the luminances of the green and blue primaries fulfil this ratio with the red luminance. Even with the duty cycle of the red driving condition at 100% duty cycle, the inherent low brightness of the long-wavelength red emission means that in order to fulfil this luminance ratio, the green and blue driving duty cycles must be made very short. In the case of the shortest primary wavelength (blue), in order to give a blue luminance that will balance with the red luminance, the blue duty cycle must be close to zero.

Driving short-wavelength emission with very short duty cycles creates difficulties with display control. If the duration of pulse width modulation (the duty cycles) of the driving conditions are too short for blue and green primary emission wavelengths, the least significant bit LSB (ie. the emission wavelength that requires the shortest duty cycle) time for PWM will be too short to be achieved. MicroLED inherited capacitance will also cause poor performance in low grayscales.

The present invention ameliorates the problem of overly-short duty cycles for shorter, brighter emission wavelengths, by providing a wavelength-specific absorptive colour filter.

In the present invention, the absorptive colour filter is configured to attenuate, or reduce, the transmitted luminance of one or more emission wavelengths of the variable-wavelength LED. The attenuation provided by the absorptive colour filter allows longer duty cycles to be used to drive emission wavelengths such as the second emission wavelength.

The absorption of light by the absorptive colour filter means there is a difference between the luminance of emitted light at the point that it is emitted by the variable-wavelength LED, and the luminance of the same emitted light after it has been transmitted through the filter.

The absorptive colour filter may be configured so that in use, light emitted at the first emission wavelength has a first luminance L₁ prior to transmission through the absorptive colour filter, and a first transmitted luminance L_{IT} after transmission through the absorptive colour filter, and light emitted at the second emission wavelength has a second luminance L₂ prior to transmission through the absorptive colour filter, and a reduced second transmitted luminance L_{2T} after transmission through the absorptive colour filter.

Thanks to the absorptive colour filter reducing the brightness of light at the second emission wavelength, instead of having to use a very short second duty cycle to create the required second luminance L₂ of the second emission wavelength, a longer and more practical second duty cycle may be used for the second driving condition. This longer second duty cycle causes the second emission wavelength to be emitted with a second luminance L₂ which is higher than desired for the output signal, but the absorptive colour filter counteracts this by partially absorbing the light at the second wavelength, and reducing the brightness of that light to a second transmitted luminance L_{2T}. The second transmitted luminance L_{2T} is advantageously the desired output luminance for light emitted at the second emission wavelength.

As a viewer observing the display device perceives an output signal which is the combination of the emitted wavelengths transmitted through the filter, it is the transmitted luminances (the luminances exiting the absorptive filter) of the first and second emission wavelengths which combine to create the perceived output signal. The absorptive colour filter may thus be designed to absorb a desired proportion of light at the second emission wavelength, so that the transmitted first and second luminances fulfil a desired brightness-balance ratio.

The absorptive colour filter may preferably be configured to reduce, or modulate, the luminance of light having the second emission wavelength, so that in use, light emitted at the second emission wavelength has a second luminance L₂ prior to transmission through the absorptive colour filter, and a reduced second transmitted luminance L_{2T} after transmission through the absorptive colour filter, such that L_{2T}<L₂.

Preferably the absorptive colour filter is configured not to reduce the luminance of light having the first emission wavelength, so that the magnitude of the first transmitted luminance L_{1T} is at least 90%, or at least 92%, or at least 95%, or at least 98% of the magnitude of the first luminance L₁. As the first emission wavelength may be a long emission wavelength for which brightness is a limiting factor even at 100% duty cycle, it may be preferred that the first emission wavelength is transmitted through the absorptive colour filter with as high an intensity as possible.

Due to the inherent characteristics of the filter, it may be inevitable that some small proportion of light having the first emission wavelength is absorbed by the filter. The absorptive colour filter thus may be configured to absorb light emitted at the second emission wavelength to a greater degree than light emitted at the first emission wavelength, so that the ratio of L_{2T}:L_{1T} is lower than the ratio of L₂:L₁.

As described above, control of the display device may be simplified by driving the variable-wavelength LED to emit light at a plurality of selected “primary” emission wavelengths.

Output signals may thus be created by combining pulses of the primary emission wavelengths, and varying the mixing ratios of the primary wavelengths within that combination. As such, the “first emission wavelength”, “second emission wavelength” and “third emission wavelength” described throughout this document may alternatively be defined as first, second and third “primary emission wavelengths”.

The variable-wavelength LED is preferably controllable to emit light at two, or three, or more than three selected primary emission wavelengths, such that in use the light transmitted out of the outlet of the display device during a display frame forms an observed signal which is the temporal combination of the primary emission wavelengths emitted by the variable-wavelength LED during the display frame.

The first and second emission wavelengths may be first and second primary emission wavelengths.

The display device may comprise a controller programmed to drive the variable-wavelength LED to emit the first and second emission wavelengths in response to first and second respective driving conditions, the first and second emission wavelengths being wavelengths within the emission wavelength range of the variable-wavelength LED.

The controller may be programmed to drive the variable-wavelength LED in a field-sequential mode to emit the first and second emission wavelengths within discrete subframes of the same display frame.

The first emission wavelength has a longer wavelength than the second primary emission wavelength, and due to the correlation of brightness and current density, the first wavelength has a lower luminance than the second primary emission wavelength if the duty cycles of the first and second driving conditions are equal.

The first driving condition may be a first current density, and the second driving condition may be a second current density greater in magnitude than the first current density.

Alternatively the first driving condition may be a first voltage, and the second driving condition may be a second voltage greater in magnitude than the first voltage.

The absorptive colour filter may be configured to reduce the luminance of the second emission wavelength emitted by the variable-wavelength LED, and the absorptive colour filter may preferably be configured not to reduce the luminance of the first emission wavelength emitted by the variable-wavelength LED.

The absorptive colour filter may be configured to reduce the luminance of the second emission wavelength emitted by the variable-wavelength LED, and the absorptive colour filter may be configured to reduce the luminance of the first emission wavelength by a lower proportion than it reduces the luminance of the second emission wavelength.

The first emission wavelength, or the first primary emission wavelength, may be a red emission wavelength of above 595 nm or above 630 nm. Preferably the first emission wavelength is between 595 nm and 700 nm, or between 610 nm and 680 nm, preferably between 625 nm and 670 nm.

The second emission wavelength is preferably less than 595 nm, or less than 570 nm.

In a preferred embodiment, the second emission wavelength is a green emission wavelength of between 500 nm and 590 nm, or between 510 nm and 580 nm, preferably between 525 nm and 570 nm. In an alternative preferred embodiment, the second emission wavelength is a blue emission wavelength of below 495 nm, preferably between 400 nm and 490 nm, or between 410 nm and 480 nm, preferably between 430 nm and 470 nm.

The first and second emission wavelengths, or first and second primary emission wavelengths, are preferably at least 40 nm apart, or at least 50 nm apart within the emission wavelength range of the variable-wavelength LED.

The display may comprise a plurality of absorptive colour filters, each absorptive colour filter being configured to attenuate the luminance of light emitted at a respective (primary) emission wavelength.

The variable-wavelength LED, or the second LED subpixel, or a third LED subpixel, is preferably driveable to emit light at a third emission wavelength in response to a third electrical driving condition. Preferably the variable-wavelength LED is driveable to emit light at the third emission wavelength in response to the third electrical driving condition, the first, second and third emission wavelengths being within the emission wavelength range of the variable-wavelength LED.

The absorptive colour filter is preferably configured to attenuate the luminance of light emitted at the third emission wavelength as well as the luminance of light emitted at the second emission wavelength.

The absorptive colour filter may be configured to reduce, or attenuate, the luminance of light having the third emission wavelength, so that in use, light emitted at the third emission wavelength has a third luminance L₃ prior to transmission through the absorptive colour filter, and a reduced third transmitted luminance L_{3T} after transmission through the absorptive colour filter.

Alternatively, the absorptive colour filter may be a second-emission-wavelength-absorptive filter configured to attenuate the luminance of the second emission wavelength, and the device may comprise an additional third-emission-wavelength-absorptive filter which is configured to attenuate the luminance of the third emission wavelength.

The first, second and third wavelengths may be first, second and third primary emission wavelengths, such that the display device is controlled to drive the variable-wavelength LED to emit light at the discrete first, second and third primary emission wavelengths instead of at a continuum of emission wavelengths.

The display device may comprise a controller programmed to drive the variable-wavelength LED to emit the first, second and third emission wavelengths in response to respective first, second and third driving conditions.

The controller may be programmed to drive the variable-wavelength LED in a field-sequential mode to emit the first, second and third emission wavelengths within discrete subframes of the same display frame. For example the controller may be programmed to drive the variable-wavelength LED to emit three or more primary emission wavelengths within the emission range of the variable-wavelength LED, by supplying first, second and third driving conditions to the variable-wavelength LED in discrete sequential subframes of a display frame, so that the variable-wavelength LED emits the first primary emission wavelength λ_{P1}, the second primary emission wavelength λ_{P2} and the third primary wavelength λ_{P3} in respective subframes.

The first emission wavelength preferably has a longer wavelength than the second and third primary emission wavelengths, and light emitted by the variable-wavelength LED at the first emission wavelength may thus inherently have a lower luminance than light emitted at the second and third primary emission wavelengths if the first, second and third duty cycles of the first, second and third driving conditions are equal.

The absorptive colour filter may be configured to reduce the luminance of light emitted at the second emission wavelength, and to reduce the luminance of light emitted at the third emission wavelength, while the absorptive colour filter is configured not to reduce the luminance of light emitted at the first emission wavelength. As discussed above, the luminance of the shortest primary emission wavelength is the limiting factor for overall display brightness, so it may be preferable to filter only shorter emission wavelengths, so that longer duty cycles can be used to generate the shorter emission wavelengths while still maintaining the required colour- and brightness-balance at the display outlet.

The absorptive colour filter may be configured to reduce the luminance of the light emitted by the variable-wavelength LED at the second and third emission wavelengths, and to reduce the luminance of the light emitted at the third emission wavelength by a different proportion than it reduces the luminance of light emitted at the second emission wavelength.

The third emission wavelength may preferably be less than 595 nm, particularly preferably less than 570 nm, or less than 495 nm.

In a preferred embodiment, the second emission wavelength is a green emission wavelength of between 500 nm and 590 nm, or between 510 nm and 580 nm, preferably between 525 nm and 570 nm, and in which the third emission wavelength is a blue emission wavelength of below 495 nm, preferably in which the third emission wavelength is between 400 nm and 490 nm, or between 410 nm and 480 nm, preferably between 430 nm and 470 nm. The second and third emission wavelengths may thus be green and blue primary wavelengths respectively.

The first, second and third primary emission wavelengths are preferably at least 40 nm apart, or at least 50 nm apart from one another within the emission wavelength range of the variable-wavelength LED, so that the highest and lowest of the first, second and third emission wavelengths are separated by at least 80 nm, or at least 100 nm. Having the first, second and third primary emission wavelengths spread across a wide range of the emittable wavelengths advantageously allows a large colour gamut to be displayed by combining pulses of the three emission wavelengths in different mixing proportions.

The absorptive colour filter may be configured to attenuate the luminance of the second emission wavelength from a second luminance L₂, which is emitted by the variable-wavelength LED, to a transmitted second luminance L_{2T}, so that when calibrated first and second duty cycles are used the wavelengths and transmitted luminances of the first and second emission wavelengths are complementary and sum to a standard illuminant point.

The display device can preferably be driven so that the wavelengths and transmitted luminances of the first and second emission wavelengths are complementary and sum to the standard illuminant point.

The absorptive colour filter may be configured to attenuate the luminance of the second emission wavelength from a second luminance L₂, which is emitted by the variable-wavelength LED, to a second transmitted luminance L_{2T}, and to attenuate the luminance of the third emission wavelength from a third luminance L₃, which is emitted by the variable-wavelength LED, to a third transmitted luminance L_{3T}.

The display device can preferably be driven so that the wavelengths and transmitted luminances of the first, second and third emission wavelengths are complementary and sum to a standard illuminant point.

The standard illuminant point may be a white point. Particularly preferably the standard illuminant point is CIE standard illuminant point D65.

The absorptive colour filter may comprises a glass substrate, or a plastic substrate, or a semiconductor-film substrate.

The absorptive colour filter can be made from glass, plastic or film substrates by utilizing the material's inherent absorption or transmission properties, rather than interference effects from thin film coatings. The absorptive colour filter may comprise a combination of semiconductor thin film materials based on the wavelength which the filter is intended to attenuate. The absorptive colour filter may comprise one or more layers of absorptive material, and the layer thickness may be varied to provide colour filters which attenuate different wavelengths of transmitted light. By controlling the thickness of the material, precise filtering across large wavelength bandwidths can be achieved.

Suitable absorptive colour filters are widely used in photography, optical instrument and illumination devices, and are available to those skilled in the art.

The absorptive colour filter may be a longpass filter. Alternatively the absorptive colour filter may be a bandpass filter. Alternatively the absorptive colour filter may be a lowpass filter.

The absorptive colour filter is preferably configured not to alter the wavelengths of the light emitted by the variable-wavelength LED. The absorptive colour filter is preferably not a wavelength conversion layer. For example the filter is preferably configured to absorb a proportion of certain emitted wavelengths, but preferably does not comprise colour conversion materials for re-emitting absorbed light.

The variable-wavelength LED is preferably a microLED. Particularly preferably the variable-wavelength LED is a III-nitride LED.

The variable-wavelength LED may have an emission wavelength range with a width of between 100 nm and 200 nm, or between 125 nm and 185 nm, or between 150 nm and 175 nm. The variable-wavelength LED is preferably continuously controllable over the emission wavelength range by varying the electrical driving condition provided to the variable-wavelength LED. Instead of continuously varying the emission wavelength within this range, however, the display device may instead be controlled by driving the variable-wavelength LED to emit light at only specific selected wavelengths—the primary emission wavelengths. Output signals with desired chromaticities and luminances can then be created as an observed temporal combination of the multiple discrete primary emission wavelengths emitted during a display frame.

The emission wavelength range preferably extends from a lower limit, which is preferably below 500 nm or below 450 nm, to an upper limit, which is preferably above 595 nm or above 630 nm.

The lower limit of the emission wavelength range may preferably between 440 nm and 495 nm, or between 440 nm and 485 nm, preferably between 450 nm and 470 nm.

The upper limit of the emission wavelength range may preferably be between 595 nm and 700 nm, or between 610 nm and 680 nm, preferably between 625 nm and 670 nm.

The variable-wavelength LED may have a FWHM of 50 nm or less, or 40 nm or less, or 30 nm or less, or 20 nm or less.

The display device may comprise an array of variable-wavelength LEDs, each variable-wavelength LED being a pixel of the device, or one of a plurality of subpixels of a device pixel.

The absorptive colour filter is preferably positioned over a plurality of variable-wavelength LEDs between the variable-wavelength LEDs and an outlet of the display device, such that light emitted by the plurality of variable-wavelength LEDs passes through the absorptive colour filter before passing out of the outlet of the display device. For example the filter may extend over the entire array of variable-wavelength LEDs in the device.

### Method of Calibration

In a second aspect of the invention there is provided a method of calibrating a display device comprising a variable-wavelength LED, the variable-wavelength LED being a pixel of the device, or one of a plurality of subpixels of a device pixel, and an absorptive colour filter, the absorptive colour filter being positioned between the variable-wavelength LED and an outlet of the display device, such that light emitted by the variable-wavelength LED passes through the absorptive colour filter before passing out of the outlet of the display device.

The method of calibration may comprise the steps of:
driving the variable-wavelength LED, or a second LED subpixel, with a first driving condition for a first duty cycle to emit a first emission wavelength λ₁ of the device, with a first luminance L₁, in which the first emission wavelength is transmitted out of the absorptive colour filter with a first transmitted luminance L_{1T};
driving the variable-wavelength LED with a second driving condition for a second duty cycle to emit a second emission wavelength λ₂ of the device, with a second luminance L₂, the second emission wavelength being shorter than the first emission wavelength;
in which the absorptive colour filter is configured to attenuate the second luminance L₂ of the second emission wavelength so that the second emission wavelength is transmitted out of the absorptive colour filter with a second transmitted luminance L_{2T}, wherein L_{2T}<L₂;
setting the second duty cycle to a shorter duration than the first duty cycle, and controlling the duration of the second duty cycle so that the first and second emission wavelengths λ₁, λ₂ and the transmitted first and second luminances L_{1T}, L_{2T} are complementary and sum to a standard illuminant point.

The duration of the second duty cycle is preferably controlled to find a calibrated second duty cycle, at which the first and second emission wavelengths λ₁, λ₂ and the transmitted first and second luminances L_{1T}, L_{2T} are complementary and sum to the standard illuminant point.

The first and second emission wavelengths emitted by the variable-wavelength LED are transmitted through the absorptive filter, and a viewer observing the outlet of the display device perceives the device as emitting an output signal which is a combination of the light transmitted through the absorptive filter at the first and second emission wavelengths. The output signal which is transmitted through the filter and observable by a viewer has an output chromaticity which is a temporal average of the emission wavelengths emitted by the variable-wavelength LED, and an output luminance L_{O} which is the temporal average of the transmitted luminances of the emission wavelengths emitted by the variable-wavelength LED.

The method of calibration is preferably a method of calibrating the display device according to the first aspect of the invention described above. Display devices calibratable using the method of the second aspect may have any of the features described in relation to the first aspect of the invention.

The method of the present invention may be a method of calibrating a display device to display an output signal with a desired output chromaticity and output luminance by transmitting two or more emission wavelengths through an absorptive colour filter configured to attenuate the luminance of at least one of the emission wavelengths.

The second duty cycle is preferably controlled to compensate for the absorptive colour filter attenuating the luminance of the second emission wavelength. As the filter attenuates the second luminance, the second duty cycle may be increased (relative to the same display without the absorptive filter) so that the combined wavelengths and the combined transmitted luminances are complementary and sum to a standard illuminant point.

Preferably the standard illuminant point is a white point, such as CIE standard illuminant point D65. In this case the display device may be calibrated to emit white light from a combination of pulses of light at the first and second emission wavelengths.

In one embodiment, the display device is a subpixellated display, so that the variable-wavelength LED is a first variable-wavelength subpixel, and the method comprises the steps of driving a second LED subpixel (preferably a second variable-wavelength LED subpixel) to emit light at the first emission wavelength, and driving the first variable-wavelength subpixel to emit light at the second emission wavelength.

In other preferred embodiments, the variable-wavelength LED is a pixel of the device, which is driveable to emit both the first and second emission wavelengths by providing the first and second driving conditions at different times. In this embodiment, no second LED subpixel is present, and the method preferably comprises the steps of driving the variable-wavelength LED with a first driving condition for a first duty cycle to emit a first emission wavelength λ₁ of the device, and driving the variable-wavelength LED with a second driving condition for a second duty cycle to emit a second emission wavelength λ₂.

The absorptive colour filter is preferably configured not to reduce the first luminance of the first emission wavelength, so that the magnitude of the first transmitted luminance L_{1T} is at least 95%, or at least 98%, or at least 99% of the magnitude of the first luminance.

Preferably the first duty cycle is a 100% duty cycle, such that the first driving condition is provided to the variable-wavelength LED for 100% of the duration of a display frame (in a subpixellated display) or display subframe (in a field-sequential display). Thus the standard illuminant point is preferably obtained with the first duty cycle being a 100% duty cycle, and the second duty cycle being a calibrated second duty cycle shorter than the first duty cycle.

As described above in relation to the first aspect, the display device may be controlled to emit desired output signals by driving the variable-wavelength LED to emit light at a plurality of discrete “primary” emission wavelengths. Instead of the variable-wavelength LED being driven with continuously variable driving conditions to emit light at any emission wavelength within its emission wavelength range, by driving the variable-wavelength LED to emit light only at two or three or more “primary emission wavelengths” the display device can be operated more like a conventional three-colour display, in which desired output signals are formed from temporal combinations of three discrete emission colours. At any given time, the variable-wavelength LED may be driven to emit one of the primary emission wavelengths.

The first and second emission wavelengths may thus be first and second primary emission wavelengths which are selected for device driving.

In conventional display devices, it has always been necessary to use three or more primary emission wavelengths to obtain a 2D gamut of observable output signals. By using variable-wavelength LEDs according to the present invention, however, different sets of primaries can be used in different display frames, so a wide range of observable output chromaticities can be achieved using sets of only two complementary primary emission wavelengths at a time.

The method may comprise the step of selecting a set of two or more discrete primary emission wavelengths λ_{P} within an emission wavelength range of the variable-wavelength LED. The set of primary emission wavelengths may correspond to a set of two or more respective driving conditions; in which the first emission wavelength λ₁ is the longest of the selected primary emission wavelengths, and in which the second emission wavelength λ₂ is another of the selected primary emission wavelengths.

The step of controlling the duration of the second duty cycle controls the second transmitted luminance L_{2T} of the light emitted when the second driving condition is applied. Controlling the duration of the second duty cycle will control the luminance of the light emitted by the LED at the second emission wavelength. As the absorptive filter absorbs a proportion of the light transmitted through the filter at the second emission wavelength, the second transmitted luminance L_{2T} is also determined by the duration of the second duty cycle. A longer second duty cycle generates a higher second luminance L₂ and thus a higher second transmitted luminance L_{2T}.

In the method of calibration, the second duty cycle is controlled so that the second transmitted luminance is balanced with the first transmitted luminance, so that the first and second transmitted luminances L_{1T}, L_{2T} are complementary and sum to a standard illuminant point. A standard illuminant point may be selected, such as a D65 white point, to define an illuminant point which the display device should be able to display to a viewer.

This calibration method then balances the first and second duty cycles with the absorption characteristics of the absorptive colour filter, to ensure that the transmitted luminances of those wavelengths will balance to fulfil a colour-balance, or white-balance, condition at the standard illuminant point.

The method may comprise the step of using the first luminance L₁ as a reference luminance and the first duty cycle as a reference duty cycle, and setting the second duty cycle to a shorter duration than the first duty cycle so that the second transmitted luminance fulfils, with the first transmitted luminance L_{1T}, a standard-illuminant point colour-mixing ratio at which the emission wavelengths and transmitted luminances of the first and second emission wavelengths are complementary and sum to the standard illuminant point.

The method may comprise the step of driving the variable-wavelength LED with a third driving condition for a third duty cycle to emit a third emission wavelength λ₃ of the device, with a third luminance L₃, the third emission wavelength being shorter than the first emission wavelength.

The absorptive colour filter may be configured to attenuate the third luminance L₃ so that the third emission wavelength is transmitted out of the absorptive colour filter with a third transmitted luminance L_{3T}, wherein L_{3T}<L₃.

The method may comprise the step of setting the third duty cycle to a shorter duration than the first duty cycle, and controlling the duration of the third duty cycle so that the first, second and third emission wavelengths and the first, second and third transmitted luminances L_{1T}, L_{2T}, L_{3T} are complementary and sum to a standard illuminant point.

The duration of the third duty cycle is preferably controlled to find a calibrated third duty cycle, at which the first, second and third emission wavelengths and the transmitted first, second and third luminances L_{1T}, L_{2T}, L_{3T} are complementary and sum to the standard illuminant point.

The first, second and third emission wavelengths and the first, second and third transmitted luminances L_{1T}, L_{2T}, L_{3T} preferably sum to the same standard illuminant point described above, for example to a white point such as D65 white.

The second emission wavelength and the third emission wavelength are preferably shorter than the first emission wavelength. As a result, the second and third driving conditions will inherently require higher current densities than the first driving condition, which will mean that with equal duty cycles the second and third emission wavelengths will be emitted with higher luminances than the first luminance. In order to reduce this effect to make the first, second and third luminances sum to the standard illuminant point, the second duty cycle and the third duty cycle are made shorter than the first duty cycle, and additionally the absorptive colour filter absorbs proportions of the light at the second and third emission wavelengths. These effects reduce the second and third transmitted luminances to the levels required to sum to the standard illuminant point with the first luminance of the first emission wavelength.

The method may comprise the step of using the first luminance L₁ as a reference luminance and the first duty cycle as a reference duty cycle, and setting the second and third duty cycles to shorter durations than the first duty cycle so that the second and third transmitted luminances fulfil, with the first transmitted luminance L_{1T}, a standard-illuminant point colour-mixing ratio at which the emission wavelengths and transmitted luminances of the first, second and third emission wavelengths are complementary and sum to the standard illuminant point.

The first, second and third emission wavelengths may be first, second and third primary emission wavelengths chosen for use as discrete primaries for device control. The method of calibration may comprise a step of selecting first, second and third primary emission wavelengths for driving the variable-wavelength LED.

The method may comprise the step of selecting a set of three discrete primary emission wavelengths λ_{P} within the emission wavelength range of the variable-wavelength LED, the set of primary emission wavelengths corresponding to a set of three respective driving conditions; in which the first emission wavelength λ₁ is the longest of the selected primary emission wavelengths, and in which the second and third emission wavelengths λ₂, λ₃ are the other selected primary emission wavelengths.

The wavelengths of the primary emission wavelengths may be variable, or varied, between display frames, so that output signals of different colours can be emitted in discrete display frames.

The three or more primary emission wavelengths are preferably variable within an emission wavelength range of the variable-wavelength LED.

The wavelengths of the three or more primary emission wavelengths in any given display frame are selected to be complementary, such that the two primary emission wavelengths in the given display frame sum to a standard illuminant point.

The method of the second aspect may be a method of calibrating a display device to display an output signal with a desired output chromaticity and output luminance by emitting two or more, or three or more, primary emission wavelengths.

The method may comprise the step of looking up, or calculating, a standard-illuminant point colour-mixing ratio in which light emitted at the selected primary emission wavelengths and their respective luminances is combined in order for the combined output signal to arrive at the standard illuminant point.

The method may comprise the steps of:
calculating, using the standard-illuminant colour-mixing ratio and the first luminance L₁ at the first emission wavelength, the required transmitted luminance L_{T} at the other primary emission wavelengths which will complement the first emission wavelength and its first luminance L₁ and sum to the standard illuminant point; and
calculating a duty cycle for each of the primary emission wavelengths which will result in the required transmitted luminance from the variable-wavelength LED at each primary emission wavelength.

In a preferred embodiment, the first emission wavelength λ₁ is a red (R) wavelength.

In a particularly preferred embodiment, the first, second and third primary emission wavelengths are selected to be red (R), green (G) and blue (B) primary emission wavelengths respectively, and the first, second and third driving conditions drive the variable-wavelength LED to emit R, G and B light respectively.

The variable-wavelength LED emits red light in response to the first driving condition, green light in response to the second driving condition, and blue light in response to the third driving condition.

The first driving condition may drive the variable-wavelength LED to emit a red primary emission wavelength, and the first duty cycle may have a duration of 100% of the duration of a display subframe, so that the first luminance L₁ is the luminance emitted at the red primary emission wavelength at 100% duty cycle.

The method may comprise the step of reducing the duty cycles of the green and blue subfields until the transmitted luminances of the green and blue primary emission wavelengths fulfil the required colour-mixing ratio with the red first transmitted luminance L_{1T}.

In a preferred embodiment, the variable-wavelength LED is a device pixel, and the method of the second aspect is a method of calibrating the display for field-sequential driving of the variable-wavelength LED pixel to emit a plurality of primary emission wavelengths in sequential subframes of a display frame. The variable-wavelength LED is preferably a pixel of the display device and the method may be a method of calibrating a field-sequential display device comprising a variable-wavelength LED pixel.

In another preferred embodiment, the display device comprises a subpixellated display in which pixels of the display each comprise two or more subpixels, the variable-wavelength LED being a first subpixel of a plurality of subpixels of a device pixel.

The method of calibration may comprise a step of storing calibrated duty cycles for each of the first, second, and optionally third emission wavelengths, or the first, second, and optionally third primary emission wavelengths.

The method may comprise the steps of programming a display controller with the calibrated duty cycles for the primary emission wavelengths.

The method may comprise the step of calibrating the transmitted luminances of the primary emission wavelengths by setting the calibrated duty cycles for each set of primary emission wavelengths so that the complementary wavelengths and their respective transmitted luminances sum to the standard illuminant point.

The method may comprise the step of calibrating the transmitted luminances of the complementary primary emission wavelengths by measuring the transmitted luminance which is transmitted by the absorptive colour filter and passes out of the outlet of the display device as the variable-wavelength LED pixel is driven across its emission wavelength range.

The driving condition associated with a particular emission wavelength of the variable-wavelength LED is a specific condition of driving current and voltage which causes the variable-wavelength LED to emit a corresponding wavelength of light. The first driving condition may thus refer to a first driving current, or a first driving current density, while the second driving condition may be a second driving current, or a second driving current density, which is different in magnitude from that of the first driving condition.

The duty cycle of a driving condition refers to the duration over which said driving condition is supplied to an LED (the “on time” of the LED), relative to the duration of a display frame, or a display subframe allocated to that subfield. The driving conditions are preferably provided in a pulse-width-modulated (PWM) manner, and the duty cycle of a driving condition defines the width of a driving current pulse relative to the time duration of the frame/subframe used for driving the device.

The method is preferably a method of calibrating a display device to emit a desired output signal using a combination of two or three primary wavelengths.

The method may comprise the step of repeating the method for a plurality of sets of two primary emission wavelengths, or a plurality of sets of three primary emission wavelengths.

The display device may comprise a plurality of variable-wavelength LEDs arranged in an array, each variable-wavelength LED being a pixel of the device, or one of a plurality of subpixels of a device pixel. The method of calibration may comprise carrying out the steps of the second aspect on each of the variable-wavelength LEDs in the display device.

### Method of Driving a Display

In a third aspect, the invention may provide a method of driving a display device comprising a variable-wavelength LED, the variable-wavelength LED being a pixel of the device, or one of a plurality of subpixels of a device pixel, and an absorptive colour filter, the absorptive colour filter being positioned between the variable-wavelength LED and an outlet of the display device, such that light emitted by the variable-wavelength LED passes through the absorptive colour filter before passing out of the outlet of the display device.

The method of driving the display device may comprise the steps of:
driving the variable-wavelength LED, or a second LED subpixel, with a first driving condition for a first duty cycle to emit a first emission wavelength λ₁ of the device, with a first luminance L₁, in which the first emission wavelength is transmitted out of the absorptive colour filter with a first transmitted luminance L_{1T};
driving the variable-wavelength LED with a second driving condition for a second duty cycle to emit a second emission wavelength λ₂ of the device, with a second luminance L₂, the second emission wavelength being shorter than the first emission wavelength;
in which the absorptive colour filter is configured to attenuate the second luminance L₂ of the second emission wavelength so that the second emission wavelength is transmitted out of the absorptive colour filter with a second transmitted luminance L_{2T}, wherein L_{2T}<L₂;
in which the duration of the first and second duty cycles are controlled so that an output signal emitted from the outlet of the display device has an output chromaticity and an output luminance L_{O}.

In one embodiment, the display device is a subpixellated display, so that the variable-wavelength LED is a first variable-wavelength subpixel, and the method comprises the steps of driving a second LED subpixel (preferably a second variable-wavelength LED subpixel) to emit light at the first emission wavelength, and driving the first variable-wavelength subpixel to emit light at the second emission wavelength.

In other preferred embodiments, the variable-wavelength LED is a pixel of the device, which is driveable to emit both the first and second emission wavelengths by providing the first and second driving conditions at different times. In this embodiment, the method preferably comprises the steps of driving the variable-wavelength LED with a first driving condition for a first duty cycle to emit a first emission wavelength λ₁ of the device, and driving the variable-wavelength LED with a second driving condition for a second duty cycle to emit a second emission wavelength λ₂.

The step of driving the pixel or subpixel to emit light at separate emission wavelengths within a display frame is achieved by providing electrical driving conditions (for example an electrical driving current) to the pixel or subpixels. The properties of the driving condition supplied to the variable-wavelength LED at any given time will determine the wavelength and associated luminance emitted by the variable-wavelength LED.

The step of driving the pixel to emit light at the first and second emission wavelength within a display frame may be achieved by driving the variable-wavelength LED in a field-sequential manner, so that discrete driving conditions are supplied in sequential subframes of the display frame and the variable-wavelength LED emits both emission wavelengths in a sequence within the display frame.

Alternatively the step of driving the subpixels to emit light at a plurality of emission wavelengths within a display frame may be achieved by driving the variable-wavelength LED subpixel to emit the second emission wavelength, and driving a separate subpixel (preferably a separate variable-wavelength LED subpixel) to emit the first emission wavelength and/or a third emission wavelength.

The output signal emitted from the outlet of the display device is a made up of light which has been emitted by the variable-wavelength LED and transmitted through the absorptive colour filter. The output signal which is observed by a viewer is the temporal average of the pulses of light emitted by the variable-wavelength LED during a display frame. The skilled person will appreciate that the frame rate, and the duration of individual display frames, may be varied as is known in the art.

The durations of the first and second duty cycles, during which the first and second driving conditions are supplied to the variable-wavelength LED, are preferably controlled to determine the output chromaticity and the output luminance of the output.

By varying the duty cycles (the widths) of the driving condition pulses provided to the variable-wavelength LED, the brightness of each pulse of emitted light can be controlled. By varying the ratio between different emission wavelengths emitted within the same display frame, the output chromaticity which will be perceived by a viewer can be controlled.

It may be desirable for the output signal to have an output chromaticity and an output luminance which match a standard illuminant point, such as a white point, for example D65 white. By calibrating the display device to produce this standard illuminant point, the device can be controlled to output D65 white light on demand. In order to do this, the second duty cycle may have a shorter duration than the first duty cycle, and the duration of the second duty cycle may be controlled so that the first and second emission wavelengths λ₁, λ₂ and the transmitted first and second luminances L_{1T}, L_{2T} are complementary and sum to the standard illuminant point.

The method of driving a display device is preferably a method of driving the display device according to the first aspect of the invention described above. Display devices driveable using the method of the third aspect may have any of the features described in relation to the first aspect of the invention, and may preferably have been calibrated using the method of the second aspect described above.

The second duty cycle for which the variable-wavelength LED with a second driving condition is preferably a calibrated second duty cycle obtained from the method of calibration described above.

The output chromaticity and the output luminance are preferably determined by an input signal provided to the display device. The display device may receive an input signal determining the chromaticities and luminances to be displayed at the outlet of the display device, and the variable-wavelength LED may then be driven to produce the desired output chromaticity and luminance by controlling the durations of the first and second duty cycles.

The method of driving the display device may be a method of driving the display device of the first aspect of the invention, and/or a method of driving a display device following the method of calibration of the second aspect of the invention, and may comprise the steps of:
driving the variable-wavelength LED with the first driving condition for the first duty cycle to emit the first emission wavelength λ₁ of the device, with the first luminance L₁, in which the first emission wavelength is transmitted out of the absorptive colour filter with the first transmitted luminance L_{1T};
driving the variable-wavelength LED with the second driving condition for the calibrated second duty cycle to emit the second emission wavelength λ₂ of the device, with the second luminance L₂, the second emission wavelength being shorter than the first emission wavelength;
in which the absorptive colour filter attenuates the second luminance L₂ so that the second emission wavelength is transmitted out of the absorptive colour filter with the second transmitted luminance L_{2T}, wherein L_{2T}<L₂;
and controlling the duration of the first and second duty cycles so that an output signal emitted from the outlet of the display device has an output chromaticity and an output luminance L_{O}.

The method may comprise the step of driving the variable-wavelength LED, or the second LED subpixel (if present), with a third driving condition for a third duty cycle to emit a third emission wavelength λ₃ of the device, with a third luminance L₃, the third emission wavelength being shorter than the first emission wavelength. The absorptive colour filter may preferably attenuate the third luminance L₃ so that the third emission wavelength is transmitted out of the absorptive colour filter with a third transmitted luminance L_{3T}, wherein L_{3T}<L₃.

The method may comprise the step of controlling the duration of the first, second and third duty cycles so that an output signal emitted from the outlet of the display device has an output chromaticity and an output luminance L_{O}

The method may comprise the step of setting the third duty cycle to a shorter duration than the first duty cycle, and controlling the duration of the third duty cycle so that the first, second and third emission wavelengths and the first, second and third transmitted luminances L_{1T}, L_{2T}, L_{3T} are complementary and sum to a standard illuminant point.

Preferably the second emission wavelength and the third emission wavelength are shorter than the first emission wavelength. The relative durations of the first, second and third duty cycles will depend on the output chromaticity and output luminance which the variable-wavelength LED is being driven to create in a given display frame.

The first, second, and optionally third, emission wavelengths are preferably discrete primary emission wavelengths at which the variable-wavelength is driven, so that the outlet signal is formed from a combination of emitted pulses having those primary emission wavelengths.

The method of driving the display device may be a method of driving the display device of the first aspect of the invention, and/or a method of driving a display device which has been calibrated using the method of calibration of the second aspect of the invention, and may comprise the steps of:
driving the variable-wavelength LED with the first driving condition for the first duty cycle to emit a first primary emission wavelength λ₁ of the device, with the first luminance L₁, in which the first primary emission wavelength is transmitted out of the absorptive colour filter with the first transmitted luminance L_{1T};
driving the variable-wavelength LED with the second driving condition for the calibrated second duty cycle to emit the second primary emission wavelength λ₂ of the device, with the second luminance L₂, the second primary emission wavelength being shorter than the first emission wavelength;
in which the absorptive colour filter attenuates the second luminance L₂ so that the second primary emission wavelength is transmitted out of the absorptive colour filter with the second transmitted luminance L_{2T}, wherein L_{2T}<L₂;
driving the variable-wavelength LED with a third driving condition for a third duty cycle to emit a third primary emission wavelength λ₃ of the device, with a third luminance L₃, the third emission wavelength being shorter than the first emission wavelength;
in which the absorptive colour filter attenuates the third luminance L₃ so that the third primary emission wavelength is transmitted out of the absorptive colour filter with a third transmitted luminance L_{3T}, wherein L_{3T}<L₃
and controlling the duration of the first, second and third duty cycles so that an output signal emitted from the outlet of the display device has an output chromaticity and an output luminance L_{O}.

In one embodiment, the display device is driven so that the outlet chromaticity and luminance correspond to standard illuminant point such as D65 white. To display the standard illuminant point to which the device has been calibrated, the respective duty cycles of the subfields driving the three primary emission wavelengths are preferably calibrated duty cycles obtained from the method of the second aspect.

In a preferred embodiment, the method is a field-sequential driving method for driving a display device comprising a variable-wavelength LED pixel, comprising the steps of: driving the variable-wavelength LED pixel to emit light at three or more primary emission wavelengths in response to respective driving conditions in respective sequential subframes of the display frame.

The method may comprise the step of driving the variable-wavelength LED pixel by supplying, during each subframe, one of three driving conditions to the variable-wavelength LED, the three driving conditions corresponding to emission of the three primary emission wavelengths.

The method may comprise repeating the driving steps for each subsequent display frame.

The method may comprise the step of increasing the duty cycle of a driving condition to increase the luminance of the respective primary emission wavelength emitted during that subframe.

The method may comprise the step of decreasing the duty cycle of a driving condition to decrease the luminance of the respective primary emission wavelength emitted during that subframe.

The method may comprise the step of selecting, for each display frame, the set of three or more primary emission wavelengths to be emitted during the display frame.

The method may comprise the step of selecting different sets of primary emission wavelengths for different display frames.

The method may comprise the step of dividing the display frame into a plurality of subframes, in which the number of subframes is 3 or more.

Each primary emission wavelength is preferably displayed in one or more display subframes during a display frame.

In a given display frame the variable-wavelength LED is preferably driven to emit light at three or more discrete primary emission wavelengths during discrete subframes.

The display device may comprise a plurality of variable-wavelength LEDs arranged in an array, each variable-wavelength LED being a pixel of the device, or one of a plurality of subpixels of a device pixel. The method of driving the display device may comprise separately driving each of the variable-wavelength LEDs in the display device, so that each variable-wavelength LED emits its own output signal. The output signals may be the same for separate variable-wavelength LEDs, so that two or more pixels/subpixels display the same output chromaticity and luminance, or the output signals may differ between variable-wavelength LEDs.

The skilled person will appreciate that the features described above in relation to the first aspect of the invention are equally applicable to the second and third aspects, and vice versa.

### Opto-Electronic Display Device

The display device used in the present invention is preferably an opto-electronic display device comprising:
a driver wafer comprising a driver circuit; and
a pixel matrix formed by an array of variable-wavelength LEDs, each variable-wavelength
LED being connected to the driver circuit and configured to receive a tunable driving signal.

Display devices according to the present invention preferably have a display screen which is made up of an array of variable-wavelength LEDs. Each variable-wavelength LED acts as a pixel or a subpixel, so that the array of variable-wavelength LEDs forms a pixel matrix.

Each pixel of the display is preferably a variable-wavelength LED which responds to different driving current densities, or different driving voltages, by emitting different peak emission wavelengths.

The driver circuit may be configured to control the power or the current or the voltage of the power supply to each variable-wavelength LED in the pixel matrix. The driver circuit may be configured to provide a pulsed, or CW, or quasi-CW power supply to the variable-wavelength LEDs.

Each variable-wavelength LED has an epitaxial structure which preferably comprises an n-doped region, a p-doped region, and a light-emitting region arranged between the n-doped region and the p-doped region.

Each variable-wavelength LED may comprise a porous region of III-nitride material epitaxially connected to the variable-wavelength LED epitaxial structure.

Particularly preferably, each variable-wavelength LED in the pixel matrix has the same device epitaxial structure. As the array of variable-wavelength LEDs may be formed by etching a single epitaxial structure into a plurality of separate LED device mesas, the composition and layer arrangement of each of the device mesas will be the same.

Although the epitaxial layer design of each variable-wavelength LED is the same, different LEDs may optionally have different lateral sizes, such that different variable-wavelength LEDs have light-emitting areas of different sizes.

Preferably each variable-wavelength LED in the pixel matrix is electrically coupled to its own CMOS driver in the driver circuit, such that each pixel (each variable-wavelength LED) is independently driveable by the driver circuit.

The LED epitaxial device structure of the variable-wavelength LEDs comprise a light-emitting region which preferably comprises a multiple quantum well (MQW) containing a plurality of quantum wells (QWs), or quantum dots, quantum wires, or other quantum nanostructures.

An LED comprises an n-doped portion, a p-doped portion, and a light-emitting region located between the n-doped portion and a p-doped portion, the light-emitting region comprising a light-emitting layer which emits light at a peak emission wavelength under electrical bias thereacross.

### Variable-Wavelength LEDs

In a particularly preferred embodiment, each variable-wavelength LED in the display has the same the variable-wavelength LED device epitaxial structure, such that each variable-wavelength LED in the display device is a separate variable-wavelength LED which is configured to emit a variable peak emission wavelength in response to variations in the driving current provided to that LED. By driving the variable-wavelength LED pixels separately through a driver circuit it is thus advantageously possible to tune the emission wavelength of each pixel individually by providing different driving currents to the variable-wavelength LED pixels.

The variable-wavelength LEDs are configured to emit a variable peak emission wavelength in response to variations in the electrical driving signal (variations in the driving current or driving voltage) provided to the LED. The peak emission wavelength of the LED is preferably continuously controllable over an emission wavelength range of at least 40 nm by varying the driving current to the LED. The peak emission wavelength may preferably be variable over an emission wavelength range of at least 50 nm, or at least 60 nm, or at least 70 nm, or at least 80 nm by varying the driving current, preferably over a range of up to 100 nm or 110 nm or 120 nm or 140 nm, or 160 nm, or 180 nm, or 200 nm, or 400 nm, or 450 nm.

The display is preferably connected to a driver circuit which is configured to supply a variable-magnitude driving current or a variable-magnitude driving voltage, to the variable-wavelength LED pixels, to vary the peak emission wavelength of the variable-wavelength LED device mesas.

A variable-wavelength light emitting diode (LED) usable in the display device, and driveable and calibratable using the methods of the present invention preferably comprises:
an n-doped portion;
a p-doped portion;
a light-emitting region located between the n-doped portion and a p-doped portion, the light-emitting region comprising a light-emitting layer which emits light at a peak emission wavelength under electrical bias thereacross;
wherein the LED is configured to receive a power supply, in which the peak emission wavelength of the LED is continuously controllable over an emission wavelength range by varying, or controlling, the power supply. The peak emission wavelength of the variable-wavelength LED is preferably continuously controllable, or continuously variable, over an emission wavelength range of at least 40 nm by varying, or controlling, the power supply.

As the peak emission wavelength of the variable-wavelength LED is preferably continuously controllable, or continuously variable, over an emission wavelength range the LED can be described as a variable-wavelength LED.

The variable-wavelength emission behaviour of the LED structure is enabled by the fact that the LED structure (the n-doped portion, the light-emitting region and the p-doped portion) are grown over a template containing a porous region. The present inventors have found that the presence of a porous region of III-nitride material in the template structure prior to overgrowth of the LED structure leads to higher quality crystal growth and thus significant benefits including the possibility of varying the emission wavelength of the LED light-emitting region. The mechanism by which the porous region enables the variable wavelength emission of the LED is the subject of ongoing study. Benefits provided to the LED by the porous region include strain relaxation, lattice parameter enlargement, wafer bow reduction, and mechanical and thermal influence during the light-emitting region being grown at high temperatures.

The variable-wavelength LED is configured to receive a supply of power, or a drive current, from a power supply or LED driver. The term “power supply” is used herein to refer to the power, or current, or voltage, supplied to drive an LED during use.

The peak emission wavelength of the LED may preferably be continuously controllable, or continuously variable, over an emission wavelength range by varying, or controlling, the magnitude of a drive current provided to the variable-wavelength LED.

In traditional LED devices, changes to the driving current provided to the LED produces a very small shift in emission wavelengths, but the present inventors have found that the wavelength shift can be broadened and controlled to a greater extent than traditional LED materials. Rather than the few nm emission range of prior art devices, the LED of the present invention is controllable to emit over a far broader emission range, for example a range of at least 40 nm. As the present LED is tunable to emit over a broad wavelength range, it may be referred to as a variable-wavelength LED.

The LED may be a dynamic colour-tunable LED, in which the peak emission wavelength of the LED is tunable by varying the driving conditions provided to the LED by the driving circuit.

The LED is preferably driveable to emit at a single peak emission wavelength in response to a stable power supply, but to emit at different peak emission wavelengths in response to variations in the power supply. Thus the LED may be used to emit a particular colour for a prolonged period, or alternatively the LED may be driven to emit a variety of different wavelengths by providing varying driving conditions.

Preferably, the n-doped portion, the p-doped portion and the light-emitting region all comprise or consist of III-nitride material, preferably GaN, InGaN, AlGaN or AlInGaN

The variable-wavelength LED preferably contains a single epitaxially-grown diode structure containing the n-doped portion, the p-doped portion and the light-emitting region. Thus the variable peak emission wavelengths of the LED are all emitted by the same LED diode structure and composition.

The LED preferably comprises a porous region of III-nitride material. The light-emitting region of the LED is preferably formed over a porous region of III-nitride material. In some embodiments, one of the n-doped portion or the p-doped portion may contain the porous region of III-nitride material. In other embodiments, the n-doped portion; the p-doped portion; and the light-emitting region are provided on a substrate which comprises the porous region of III-nitride material. During epitaxial growth of the LED, the light-emitting region is preferably overgrown after the porous region has been formed.

The present inventors have found that a porous region of III-nitride material enables the same LED to emit at a range of peak emission wavelengths, rather than at one specific wavelength. The peak emission wavelength of the LED may be varied across an emission wavelength range by varying the power supply provided to the LED. The present invention therefore provides a variable-wavelength LED, which may be controlled to emit at any wavelength across a continuous emission wavelength range. By varying the driving conditions provided to the LED by the power supply, the LED is capable of emitting at any wavelength within the emission wavelength range of said LED, and not simply at discrete peak emission wavelengths.

The present inventors have found that the ability of the LED to emit at tuneable wavelengths across a broad emission range may be imparted by either incorporating a porous region of III-nitride semiconductor material into the LED structure, or forming the LED diode structure over a porous region of III-nitride semiconductor material. Benefits provided to the LED by the porous region include strain relaxation, lattice parameter enlargement, wafer bow reduction, and beneficial mechanical and thermal influences during the growth of the light-emitting region at high temperatures.

The light-emitting region of the LED is preferably formed over a porous region of III-nitride material during manufacture, so that the porous region influences the structure and mechanical properties of layers of semiconductor that are epitaxially deposited over the porous region. Layers of semiconductor material that are deposited over the porous region during growth experience benefits such as strain reduction, lattice parameter enlargement, and wafer bow reduction, which are imparted to the LED light-emitting region and affect its structure and its light-emitting behaviour.

Once the LED light-emitting (active) region has been epitaxially grown over the porous region, and the quality of the active region has been enhanced by the influence of the porous region, the beneficial effects of the porous region on the emission properties are permanently imparted to the LED active region. Thus the LED diode structure may be retained on the porous region, in which case the variable-wavelength LED comprises a porous region of III-nitride material, or alternatively, during the processing of LEDs into devices after epitaxial growth, the porous region may be removed from the LED structure.

The width of the emission wavelength range may vary depending on the structure and composition of the LED structure (the n-doped portion, light-emitting region and p-doped portion), and on the structure and porosity of the porous region. The width of the emission wavelength range may also vary depending on the size and shape of the LED (the pixel size and shape).

In preferred embodiments, the peak emission wavelength is controllable over an emission wavelength range of at least 40 nm, or at least 50 nm, or at least 60 nm, or at least 70 nm, or at least 80 nm by varying the power supply. Preferably the peak emission wavelength is controllable over an emission wavelength range of up to 100 nm, or 110 nm, or 120 nm, or 130 nm, or 140 nm, or 150 nm, or 160 nm, or 170 nm, or 180 nm, or 190 nm, or 200 nm, or 400 nm, or 450 nm. The size of the emission wavelength range obtainable by the present LED is thus far greater than the emission ranges achievable with LEDs of the prior art.

The variable-wavelength LED is advantageously controllable to emit at any peak emission wavelength within its emission wavelength range. By varying the characteristics of the power supply and LED pixel size and shape, the variable-wavelength LED may therefore be controlled to emit light at any selected peak emission wavelength within this range.

The emission wavelength of the variable-wavelength LED is preferably continuously variable across its emission wavelength range in response to driving conditions provided by a power source being varied continuously across a range of driving conditions.

The position of the emission wavelength range in the electromagnetic spectrum may also vary depending on the design of the variable-wavelength LED structure (the n-doped portion, light-emitting region and p-doped portion). For example the wavelengths contained in the emission wavelength range may depend on the number and composition of light emitting layers in the variable-wavelength LED. A large variety of LED active regions are known in the art for emitting at different wavelengths in the visible spectrum, so by light-emitting region forming the LEDs of the present invention with different light-emitting regions, emission wavelength ranges covering different portions of the spectrum may be obtained.

The variable-wavelength LED emission wavelength range may be between 400 nm and 850 nm, or between 400 nm and 800 nm, or between 400 nm and 690 nm, or between 400 nm and 675 nm. The emission wavelength range may be a sub-range within the range of 400 nm to 750 nm. The emission wavelength range may be tuned to cover any part of this range by selecting different LED active regions and controlling the size and shape of the LED pixels.

Preferably the emission wavelength range of the variable-wavelength LED extends from a lower end below 410 nm, or 430 nm, or 450 nm, or 470 nm, or 500 nm, or 520 nm, or 540 nm, or 560 nm, to an upper end above 570 nm, or 580 nm, or 600 nm, or 610 nm, or 630 nm, or 650 nm, or 675 nm. The first and second ends of the emission wavelength range may be tuned depending on the selection of LED structure and LED shape and size, as described above.

For example in preferred embodiments the lower end of the emission wavelength may be between 400 nm and 450 nm (violet) or between 450 nm and 500 nm (blue) or between 500 nm and 570 nm (green), and the upper end of the emission wavelength may be between 570 nm and 590 nm (yellow), or between 590 nm and 610 nm (orange), or between 610 and 700 nm (red).

In a preferred embodiment, the variable-wavelength LED emission wavelength range may extend from a lower end that is below 500 nm to a higher end that is above 610 nm, so that the peak emission wavelength of the LED may be varied to emit at any wavelength from blue (below 500 nm) to red (above 610 nm) by varying the power supply. Providing a single LED design that can be controlled to emit at blue wavelengths (450-500 nm), green (500-570 nm) and also at yellow (570-590 nm), orange (590-610 nm) and red (610-760 nm) is highly advantageous, and could provide significant advantages for LED displays.

In other preferred embodiments, the variable-wavelength LED emission wavelength range may extend between 520 nm and 660 nm, or between 550 nm and 650 nm, by varying the power supply to the LED.

In a particularly preferred embodiment, the peak emission wavelength is controllable between 540 nm and 680 nm, or between 560 nm and 675 nm, by varying the power supply. Thus, the same LED may be controllable to emit at a peak emission wavelength anywhere between 540 nm in the green and 680 nm in the red. Green and red LEDs have historically been more difficult to manufacture than shorter wavelength blue LEDs due to issues such as the difficulty of incorporating the required indium content into the light-emitting region. Providing a single LED design that can be controlled to emit at green wavelengths (500-570 nm) and also at yellow (570-590 nm), orange (590-610 nm) and red (610-760 nm) is therefore highly advantageous, and could provide significant advantages for LED displays.

In another preferred embodiment, the peak emission wavelength is controllable between 520 nm and 675 nm, or between 550 nm and 650 nm, by varying the power supply.

Although the variable-wavelength LED can emit across a continuous emission wavelength range, in some embodiments it may be desirable to control the LED to function in a plurality of discrete emission modes, for example in response to a power supply having a plurality of driving modes. For example by driving the LED in a plurality of different modes corresponding to discrete emission colours, a simplified colour display may be provided, in which discrete emission colours are mixed in known methods to give a desired visual effect.

The variable-wavelength LED is preferably controllable to emit at least two discrete peak emission wavelengths by varying the driving conditions provided by the power supply between two discrete driving conditions (such as two discrete magnitudes of drive current).

The LED may be controllable to emit at a first peak emission wavelength in response to a first driving condition provided by the power supply (which may be a drive current having a first magnitude), at a second peak emission wavelength in response to a second driving condition provided by the power supply (which may be a drive current having a second magnitude different from the first magnitude).

The variable-wavelength LED is preferably controllable to emit at least three discrete peak emission wavelengths by varying the driving conditions provided by the power supply. The peak emission wavelength of the variable-wavelength LED may thus be variable over at least three “colours” in the EM spectrum.

The variable-wavelength LED may be controllable to emit at a first peak emission wavelength in response to a first driving condition provided by the power supply, at a second peak emission wavelength in response to a second driving condition provided by the power supply, and at a third peak emission wavelength in response to a third driving condition provided by the power supply.

The variable-wavelength LED may preferably be controllable to emit a blue peak emission wavelength in response to a first driving condition provided by the power supply, to emit a green peak emission wavelength in response to a second driving condition provided by the power supply, and to emit a red peak emission wavelength in response to a third driving condition provided by the power supply.

The variable-wavelength LED may be controllable to emit a first peak emission wavelength in the range 400-500 nm in response to a first driving condition provided by the power supply, to emit a second peak emission wavelength in the range 500-550 nm in response to a second driving condition provided by the power supply, and to emit a third peak emission wavelength greater than 600 nm in response to a third driving condition provided by the power supply.

Preferably, the variable-wavelength LED is controllable to emit a first peak emission wavelength in the range 430-460 nm in response to a first driving condition provided by the power supply, to emit a second peak emission wavelength in the range 510-560 nm in response to a second driving condition provided by the power supply, and to emit a third peak emission wavelength in the range 600-660 nm in response to a third driving condition provided by the power supply.

The first, second and third driving conditions may be first, second and third current densities, or the first, second and third driving conditions may be first, second and third power densities.

The morphology of quantum wells (QWs) in the active light-emitting region may be varied. For example the light-emitting region may contain uniform QWs with well-defined interfaces or fragmented QWs with less well-defined interfaces, fragmentation, or QW well width/composition fluctuation or quantum dots like localisation centres. This control of QW morphology can determine the range of the variable emission wavelength to be controlled and manipulated.

The light-emitting region preferably comprises a plurality of quantum wells (QWs). The quantum wells may be continuous. The quantum wells may be fragmented, or discontinuous.

The variable-wavelength LED may comprise a current constraining layer, or a current limiting layer, which is a dielectric layer configured to confine the lateral area of the LED through which current is conducted. The use of a current constraining layer may advantageously allow further control of the current density, in order to better control the peak emission wavelength of the LED.

The current constraining layer may advantageously enable the manipulation of the power density provided to the variable-wavelength LED, in order to control the peak emission wavelength.

The current constraining layer is preferably a layer of dielectric material. For example, the current constraining layer may be any dielectric, for example SiO₂, SiN or SiNx.

The current constraining layer may be positioned in a variety of positions in the variable-wavelength LED, as long as it confines the lateral area of the LED through which current is conducted. The current constraining layer may be positioned in the LED between an electrical n-contact and an electrical p-contact.

The current constraining layer may be positioned adjacent to either the n-doped portion or the p-doped portion of the LED. For example the current constraining layer may be positioned between the n-doped portion and the light-emitting region. Alternatively the current constraining layer may be positioned between the light-emitting region and the p-doped portion. The current constraining layer may be positioned between an electrical contact and the LED structure (n-doped portion, p-doped portion and light-emitting region).

The current constraining layer preferably comprises an aperture extending through the current constraining layer, or one or more apertures extending through the current constraining layer. The aperture may preferably be positioned in the centre of the current constraining layer. For example the current constraining layer may comprise a circular opening in the centre of the LED structure.

The variable-wavelength LED may be configured so that an electrical contact is in contact with the LED structure via the aperture in the current constraining layer, so that the area of the aperture defines a contact area over which the contact and the LED structure are touching.

The lateral dimensions of the or each aperture is preferably much smaller than the lateral dimensions of the LED. By providing an aperture through the dielectric current constraining layer, high local current density may be achieved, which may advantageously enable improved control of the power through the LED.

For example the lateral width (or diameter) of the aperture may be equal to or less than 50% of the lateral width of the LED structure (the LED mesa). The width of the aperture may be equal to or less than 45%, or 40%, or 35%, or 30%, or 25%, or 20% of the width of the LED structure.

The relative area of the aperture compared to the overall area of the current constraining layer (the blocked region) may be varied to modify the local current density.

The light emitting region preferably comprises a multiple quantum well (MQW) containing a plurality of quantum wells (QWs), or quantum dots, quantum wires, or other quantum nanostructures.

In some embodiments, the light-emitting region comprises a plurality of quantum wells (QWs), and the quantum wells are continuous.

The present inventors have found that non-uniformities in the light-emitting region have a significant effect in broadening the emission wavelength range across which a light-emitting region can emit light in response to variations in the power supplied to the LED. In the prior art, non-uniformities in the light-emitting region are typically considered problematic flaws, which are unwanted and should be avoided in any way possible because the goal is typically a high-quality, low-flaw semiconductor wafer. The present inventors have eschewed this prejudice in the art, and found that intentionally creating non-uniformities in the light emitting region may advantageously broaden the emission wavelength range and result in a variable-wavelength LED which can emit over a far broader wavelength range than has ever been possible in the prior art.

In alternative embodiments of the present invention, the light-emitting region is non-uniform, fragmented, or discontinuous. The light-emitting region may be deliberately introduced to achieve the effect of carrier localisation centres in InGaN quantum wells, such as multiple types of QW region with different Indium composition and well width and quantum barriers, non-uniform, or fragmented, or broken, or gappy, or discontinuous quantum wells which would result in fluctuation in the well width, InGaN quantum dots or nanostructures, quantum wells formed on polar, semi-polar or non-polar facets.

In a preferred embodiment, the light-emitting region comprises a plurality of quantum wells (QWs), and the quantum wells are non-uniform, fragmented, or discontinuous.

The plurality of QWs may comprise fluctuations in well-width. For example the well width of the QWs may fluctuate by at least 2%, 5%, 10%, 20%, 25%, or 50%, or 75%. The well width fluctuations can be variations between quantum wells (vertical direction) as well as within one quantum well (lateral direction).

The plurality of QWs may comprise fluctuations in alloy composition. For example the indium composition of the QWs may vary by at least 2%, 5%, 10%, 20%, 25% or 50% or 75% across the light-emitting region.

The inventors have found that fluctuations in well-width and/or alloy composition may induce carrier localisation centres, either in the upper interface or lower interface of the QWs. Any carrier localisation centres would induce the variable wavelength in the variable-wavelength LED of the present invention. The larger the density of those carrier localisation centres, the larger the variable wavelength range can be achieved.

The variable-wavelength LED may comprise a v-shaped pit which extends, or propagates, through the light emitting active region. Preferably the LED comprises a plurality of v-shaped pits which extend through the light-emitting region.

Preferably the variable-wavelength LED may comprise a density of v-shaped pits (measured looking down onto the LED structure from above) of at least 1×10⁷/cm², for example at least 5×10⁷/cm² or at least 1×10⁸/cm², for example a density of v-shaped pits of 1×10⁷/cm² to 5×10⁹/cm².

The variable-wavelength LED may comprise a density of v-shaped pits of less than 5×10⁹/cm², for example a density of v-shaped pits of less than 1×10⁹/cm² or less than 5×10⁸/cm².

V-shaped pits are a phenomenon known in the art of epitaxial semiconductor growth, and methods of growing v-shaped pits in semiconductor structures are known in the art. For example, v-shaped pits and their growth are described in the prior art in The effect of nanometer-scale V-pits on electronic and optical properties and efficiency droop of GaN-based green light-emitting Diodes; Zhou et al; Scientific Reports|(2018) 8:11053|DOI: 10.1038/s41598-018-29440-4.

These v-shaped pits are v-shaped when viewed in cross-section, but in reality form as conical or funnel-shaped voids in semiconductor structures that are grown from the bottom up using conventional epitaxial growth methods. While the cross-section of the pits is v-shaped, the pits are typically hexagonal when viewed from above. The point of the v-shaped pits are always directed downwards towards earlier-deposited layers of semiconductor structure, as the pits widen as subsequent layers of epitaxial growth are deposited on top of the structure.

Although v-shaped pits are known in the art, they are typically considered a problematic flaw in semiconductor structures, which are unwanted because the goal is typically a high-quality, low-flaw semiconductor wafer.

In the unusual situations where v-shaped pits have been incorporated into semiconductor structures in the past, the v-shaped pits have been used as a screening mechanism to create higher band gap regions which prevent current carriers going down threading dislocations as a leakage path.

In some preferred embodiments of the present invention, however, v-shaped pits are intentionally incorporated into the variable-wavelength LED structure. The v-shaped pits extend far enough down into the semiconductor structure that they terminate in a layer below the active light-emitting region. This means that the v-shaped pits must extend through the thickness of the active light-emitting region.

The present inventors have found that v-shaped pits extending through the light-emitting region of the LED structure may advantageously broaden the emission wavelength range over which a variable-wavelength LED can emit.

As the v-shaped pits extend through the active region of the LED, during epitaxial growth from the bottom up, quantum well (QW) layers that are planar across the rest of the structure are grown on the sloping side walls of the v-shaped pits. The QWs deposited on the pit sidewalls are distorted and stretched around the sides of the pits, so end up being of different thickness and composition compared to the planar QWs across the bulk of the structure.

Around the v-shaped pits, QW layers of semiconductor material are grown as flat planar layers. The active light-emitting region is thus planar around the v-shaped pit. In the location of the v-shaped pits, however, the active layers are distorted and stretched downwards along the sidewalls into the v-shaped pit. This stretching effect changes the thickness of the QWs on the sidewalls of the pit, so that they are different in thickness compared to the planar QW layers formed over the rest of the LED structure.

The inventors have found that v-shaped pits can create local strain relaxation, and MQWs deposited on the sidewall of these v-pits will have different thickness and composition compared to the rest of the MQW, hence the MQW in the region of the v-shaped pits will produce a different emission wavelength.

The quantum wells grown on the side walls of the v-shaped pit are thinner than the bulk planar QWs elsewhere in the structure, which may affect the QW bandgap and allow the QWs in this region to emit at wavelengths different from those emitted by the planar QWs elsewhere in the structure. In addition to this, the QWs on the pit sidewalls may end up having a higher indium (In) content than the surrounding planar QWs, because the sidewalls expose a semipolar facet of the QWs—this facet incorporates more indium during epitaxial growth, so the QWs in the region of the v-shaped pits may be higher in indium than the planar QWs around the pits. Higher indium incorporation typically leads to longer peak emission wavelengths. Both the QW thickness and the indium content affect the emission wavelengths produced by the light-emitting region. The presence of v-shaped pits in the LED structure may thus advantageously modify the composition and thickness of QWs in the light-emitting region in a way that expands the emission wavelength range over which the LED can be driven to emit light.

V-shaped pits typically grow from threading dislocations in the semiconductor structure. The threading dislocations are perpetuated upwards through the structure as additional layers are grown over layers containing a threading dislocation, and at a certain point the dislocation widens into a v-shaped pit. Typically the skilled person aims to keep threading dislocation concentrations low in order to produce a “high quality” low-flaw wafer.

V-shaped pits can alternatively be grown using 3-dimensional epitaxial growth modes. 3D epitaxial deposition techniques are known in the art and are typically used to grow “islands” or “pyramids” of semiconductor material on a template. By controlling deposition of the LED structure using 3D epitaxial deposition techniques, v-shaped pits can be artificially grown in desired locations, with no need for a threading dislocation to be present to “seed” the formation of the v-shaped pit. By using this deposition control, the bottom (nadir) of the pit may be created at a desired location in the structure-both a desired lateral position and a desired height in the structure, for example in a particular layer of the semiconductor structure below the active light-emitting region.

The bottom of the v-shaped pit may be located in the connecting layer of the semiconductor structure. The connecting layer may be positioned between the porous region and the n-doped portion.

The bottom of the v-shaped pit may be located in a pre-strain layer of the semiconductor structure. The pre-strain layer may be positioned above the n-doped portion and below the light-emitting region.

Preferably the variable-wavelength LED comprises a plurality of v-shaped pits which extend through the active light-emitting region.

Preferably the variable-wavelength LED comprises a density of v-shaped pits (measured looking down onto the LED structure from above) of at least 1×10⁷/cm², for example at least 5×10⁷/cm² or at least 1×10⁸/cm². The LED may comprise a density of v-shaped pits of less than 5×10⁹/cm², for example a density of v-shaped pits of less than 1×10⁹/cm² or less than 5×10⁸/cm².

For example the variable-wavelength LED may comprise a density of v-shaped pits of 1×10⁷/cm² to 5×10⁹/cm², or 5×10⁷/cm² to 5×10⁹/cm², or 1×10⁸/cm² to 5×10⁸/cm².

The variable-wavelength LED may comprise more than 0.1 v-shaped pit per square micrometer, or more than 1 v-shaped pits per square micrometer, or more than 2 v-shaped pits per square micrometer.

The concentration of v-shaped pits in the variable-wavelength LED is preferably controlled, as too many v-shaped pits may negatively affect the light emission of the LED by disrupting radiative recombination. For example the LED may comprise fewer than 10 v-shaped pits per square micrometer, or fewer than 8 v-shaped pits per square micrometer, or fewer than 6 v-shaped pits per square micrometer.

In a preferred embodiment the LED structure may comprise no greater than 10\hat{ }9 threading dislocations per square centimetre. Preferably the semiconductor structure below the active light-emitting region (typically a substrate, the porous region and a connecting layer) comprise no more than 10\hat{ }9 threading dislocations per square centimetre. The threading dislocation density is preferably limited to this level so that further epitaxial growth does not create too many v-shaped pits in the light-emitting region.

Both the density and size (the depth) of the v-shaped pits may be controlled. The size of the V-pits can be controlled by the position and the growth conditions of the pre-strain layer and the low-temperature nGaN layer where the pits started.

The morphology of quantum wells (QWs) in the active light-emitting region may be varied. For example the light-emitting region may contain uniform QWs with well-defined interfaces or fragmented QWs with less well-defined interfaces, fragmentation, or QW well width/composition fluctuation or quantum dot like localisation centres. This control of QW morphology can determine the range of the variable emission wavelength to be controlled and manipulated.

The light-emitting region preferably comprises a plurality of quantum wells (QWs). The quantum wells may be continuous. The quantum wells may be fragmented, or discontinuous.

If QWs are continuous and very uniform in thickness and composition, recombination of charge carriers can only happen in regular well defined ways. On the other hand, if QWs are fragmented or discontinuous, this creates lots of nanostructures, which in turn creates different band gaps that result in emission of different colours.

The light-emitting region, and/or the LED, may have lateral dimensions (width and length) of greater than 100 μm and less than 300 μm. In this case, the LED may be termed a “mini-LED”. In preferred embodiments, the mini-LED may be square or circular or square with circular corners and have dimensions such as 300 μm×300 μm, 200 μm×200 μm, 100 μm×100 μm.

The light-emitting region, and/or the LED, may alternatively have lateral dimensions (width and length) of less than 100 μm. In this case, the LED may be termed a “micro-LED”. The micro-LED may preferably have lateral dimensions of less than 80 μm, or 70 μm, or 60 μm, or 50 μm or 30 μm, or 25 μm, or 20 μm, or 15 μm or 10 μm, or 5 μm or 3 μm or 2 μm.

In preferred embodiments, the micro-LED may be square or circular or square with circular corners and have dimensions such as 75 μm×75 μm, 50 μm×50 μm, 40 μm×40 μm, 30 μm×30 μm, 25 μm×25 μm, 20 μm×20 μm or 10 μm×10 μm, or 5 μm×5 μm, or 2 μm×2 μm, or 1 μm×1 μm, or 500 nm×500 nm or smaller.

The light-emitting region, and/or the LED, may alternatively have lateral dimensions (width and length) of less than 1 μm. In this case, the LED may be termed a “nano-LED”. The nano-LED may preferably have lateral dimensions of less than or 500 nm, or 200 nm, or 100 nm, or 50 nm.

The LEDs may be circular, triangle, rectangular, square, oval, diamond, hexagonal, pentagonal, and any combination of these shapes. In the case of irregular-shapes of pixel design, at least one dimension should fall within the dimensions defined above in order for the LEDs to be classed as mini- or micro-LEDs. For example the width or diameter of the LEDs are preferably less than 100 μm so that the LEDs are classed as micro-LEDs.

### Porous Regions

The variable-wavelength LEDs preferably comprise one or more porous regions of III-nitride material.

The n-type region, the light-emitting region and the p-type region (which may be called the LED structure, or LED diode structure) are preferably grown over a semiconductor template which contains the porous region. The semiconductor template may also contain a number of layers of semiconductor material arranged to provide a suitable substrate for the overgrowth of the LED structure.

The porous region may be a porous layer, such that the light emitting diode comprises a porous layer of III-nitride material. Preferably the porous region may be a porous layer that is continuously porous, for example formed from a continuous layer of porous III-nitride material.

The porous region may comprise a plurality of porous layers, and optionally a plurality of non-porous layers. In preferred embodiments of the invention, the porous region is a stack of alternating porous and non-porous layers, with the top surface of the stack defining the top of the porous region, and the bottom surface of the stack defining the bottom of the porous region. The light-emitting region may be formed over a porous region comprising a stack of porous layers of III-nitride material.

Each variable-wavelength LED may comprise its own porous region of III-nitride material, or alternatively a shared porous region may be epitaxially connected to a plurality of the variable-wavelength LEDs.

### BRIEF DESCRIPTION OF THE DRAWINGS

Embodiments of the invention will now be described with reference to the figures, in which:

FIG. 1A illustrates a CIE xy colour gamut and the wavelengths directly emittable by an exemplary variable-wavelength LED usable in the present invention;

FIG. 1B illustrates the CEI xy colour gamut of FIG. 1A, overlaid with two primary emission wavelengths usable for device control;

FIG. 1C illustrates the CEI xy colour gamut of FIG. 1A, overlaid with three primary emission wavelengths usable for device control;

FIG. 2 illustrates the current gain and duty cycle of three driving modes applied to one variable-wavelength LED pixel within one display frame;

FIG. 3a schematically illustrates three emission peaks emitted by the same variable-wavelength LED pixel in response to three different driving currents;

FIG. 3b schematically illustrates three emission peaks emitted by the same variable-wavelength LED pixel in response to three different driving voltages;

FIG. 4 illustrates the duty cycles of three pulses of driving current provided to the same variable-wavelength LED in three discrete subframes in a field-sequential manner;

FIG. 5 schematically illustrates the emitted luminances of three primary emission wavelengths from a variable-wavelength LED as a result of three pulses of driving current having different duty cycles;

FIG. 6 schematically illustrates a display device according to the present invention, in which an absorptive colour filter is positioned between a variable-wavelength LED and an outlet of the display device;

FIG. 7 schematically illustrates the emitted and transmitted luminances of three primary emission wavelengths from the display device of FIG. 6;

FIG. 8A shows experimental results showing the transmitted luminances measured when testing an embodiment of the invention with a suitable longpass filter;

FIG. 8B illustrates the expected absorption band of the filter tested in FIG. 8A;

FIG. 9 is a series of five EL images of the same MicroLED pixel being driven at different currents in constant wave mode (CW), showing five different colours of emission;

FIG. 10A is an emission wavelength vs current density plot for a 25 μm×25 μm 100×100 variable-wavelength LED pixel array driven in pulsed mode with a 100 μs pulse at 1% duty cycle;

FIG. 10B is an emission wavelength vs current density plot for a 30 μm×30 μm 100×100 variable-wavelength LED pixel array driven in pulsed mode with a 100 μs pulse at 1% duty cycle;

FIG. 11 is a plot of intensity vs wavelength for a single variable-wavelength LED driven at different currents in pulsed driving mode with a 100 μs pulse at 1% duty cycle;

FIGS. 12A-G illustrate alternative embodiments of non-uniform, fragmented or discontinuous light-emitting regions of variable-wavelength LEDs usable in preferred embodiments of the present invention;

FIG. 13A is a TEM image of a cross-section of a conventional non-variable-wavelength LED;

FIG. 13B is a TEM image of the light-emitting region of a variable-wavelength LED comprising v-shaped pits, usable in embodiments of the present invention;

FIG. 13C is a TEM image of the variable-wavelength LED of FIG. 12B, showing a porous region and a light-emitting region comprising a plurality of v-shaped pits, usable in a preferred embodiment of the present invention;

FIG. 14A is a graph of peak emission wavelength vs driving current density for a conventional non-variable wavelength LED;

FIG. 14B is a graph of peak emission wavelength vs driving current density for a variable-wavelength LED according to an embodiment of the present invention;

FIG. 14C is a graph of peak emission wavelength vs driving current density for a variable-wavelength LED according to another embodiment of the present invention;

FIG. 15A is a graph of peak emission wavelength vs driving current density for another variable-wavelength LED usable in embodiments of the present invention;

FIGS. 15B-D are photographs of the variable-wavelength LED of FIG. 15A, with inset emission spectra showing the different peak emission wavelengths at different driving current densities.

As described above, an optoelectronic display device containing a variable-wavelength LED can be operated to display any chromaticity within a displayable colour gamut, by selecting a plurality of primary emission wavelengths, and emitting those primary wavelengths in combination to provide a combined output signal with the desired output chromaticity and output luminance.

The size of the colour gamut which is achievable depends on the wavelengths of the primaries selected.

In the present invention a variable-wavelength LED is used to emit at least one of the primary emission wavelengths, and preferably the same variable-wavelength LED emits a plurality of primary emission wavelengths.

Variable-wavelength LEDs usable in the present invention are known as dynamic-pixel-tuning (DPT®) variable-wavelength LEDs from Poro Technologies Ltd, and are disclosed in international patent application no. PCT/GB2022/051997, published as WO2023/007174.

In preferred embodiments, the same variable-wavelength pixel is used to emit all of the selected primaries using field-sequential emission. In this case, all of the primary emission wavelengths are selected to be within the emission wavelength range of the variable-wavelength LED.

Although the present invention can be carried out using subpixellated displays in which a variable-wavelength LED emits at least one of the emission wavelengths, and one or more further primary emission wavelengths are emitted by other subpixels, the invention will be described by reference to a field-sequentially controlled embodiment in which one variable-wavelength LED forms a pixel of the display device and is driven to emit all of the selected primaries using field-sequential emission.

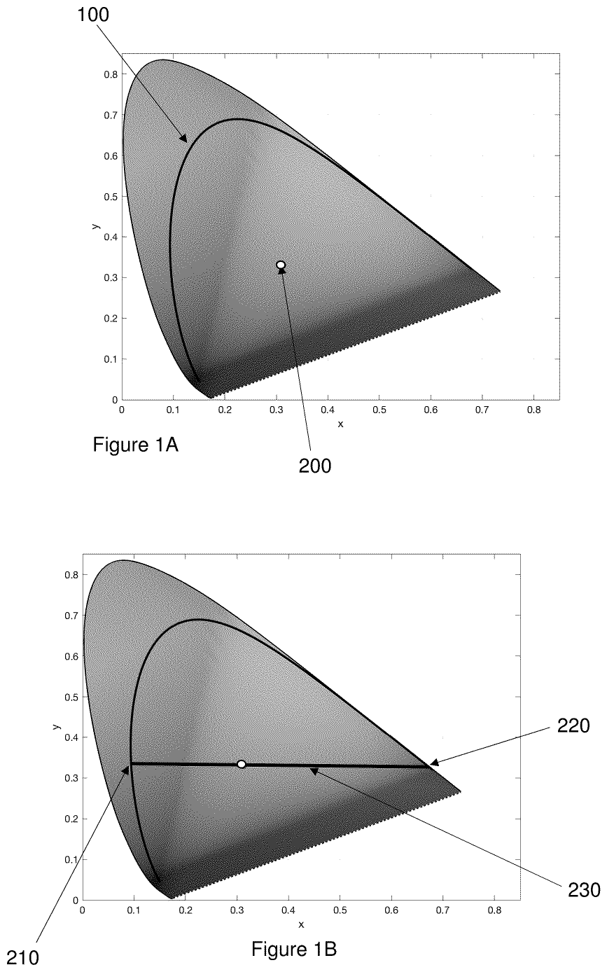

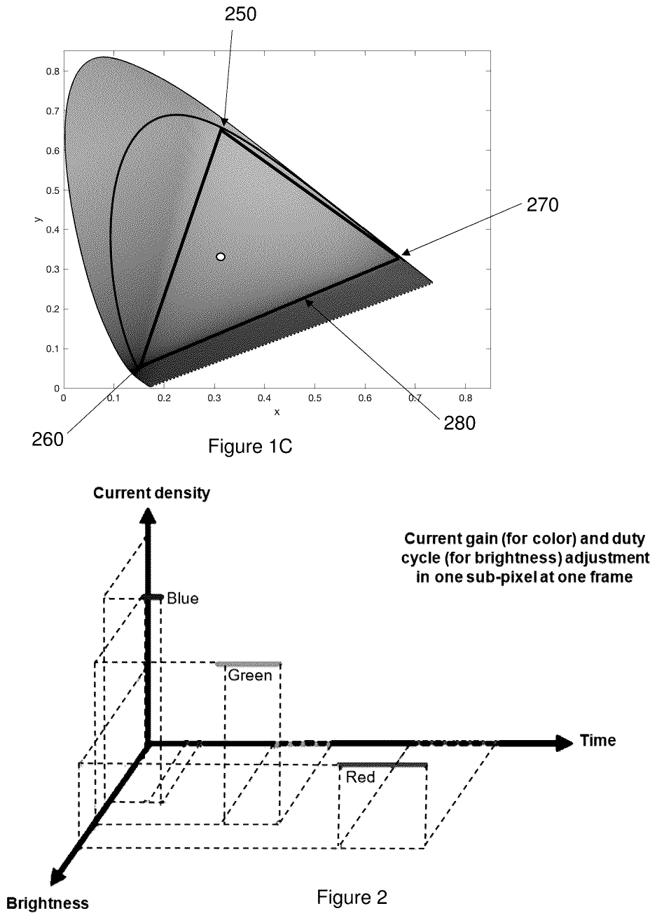

FIG. 1A illustrates the emission wavelength range (indicated by line 100) of one such variable-wavelength LED usable in the present invention, plotted in CIE xy colour space.

The variable-wavelength LED can be driven to emit any wavelength positioned on the line 100 by controlling the driving condition provided to the LED.

As described above, instead of driving variable-wavelength LEDs to emit a continuum of emission wavelengths by supplying a continuously varying driving current, such LEDs can be conveniently driven by selecting two, or three, or more than three “primary” emission wavelengths at which the variable-wavelength LED is operated. Output signals having desired output chromaticities and output luminances can then be generated from temporal combinations of pulses of light at the primary emission wavelengths, similarly to known field-sequential displays.

Unlike prior art displays, display devices incorporating variable-wavelength LEDs can be operated using only two primary emission wavelengths. FIG. 1B shows the emission wavelength range 100 of a variable-wavelength LED, from which two primary emission wavelengths 210, 220 have been selected. By varying the relative ratios of light emitted at the two primary emission wavelengths 210, 220, an output signal having any colour along the colour-mixing line 230 can be produced. The two selected primary emission wavelengths 210, 220 are complementary, so that the colour-mixing line 230 passes through the D65 white point 200, and D65 white light can be produced by mixing the two primary emission wavelengths in the required proportions. In order to emit output signals having different output chromaticity and luminance in different display frames, the two primaries may move between display frames, to different positions on the emission wavelength range 100. Moving the two primary emission wavelengths to different wavelengths advantageously moves the colour-mixing line 230 so that a variety of different colours can be produced.

Rather than using two primaries, variable-wavelength LEDs may be operated by driving the LEDs at three discrete driving conditions (for example three driving currents having different magnitudes) to emit three discrete primary emission wavelengths. FIG. 1C shows the emission wavelength range 100 of the variable-wavelength LED, overlaid with three selected primary emission wavelengths 250, 260, 270. By varying the relative ratios of light emitted at the three primary emission wavelengths, an output signal having any colour within the colour gamut triangle 280 can be produced. The three selected primary emission wavelengths 250, 260, 270 are complementary, so that the colour gamut triangle 280 contains the D65 white point 200, and D65 white light can be produced by mixing the three primary emission wavelengths in the required proportions. The positions of the three primaries in the emission wavelength range 100 may optionally be varied between display frames, depending on the desired chromaticity and luminance of the output signal.

For the sake of simplicity, the following examples reference a preferred embodiment in which three primary emission wavelengths are used to drive a variable-wavelength LED using field-sequential driving. In order to obtain a large colour gamut triangle 280 of displayable output chromaticities, in the preferred embodiment the LED is driven to emit first, second and third primary emission wavelengths which are red (R), green (G), and blue (B) respectively.

FIG. 2 illustrates the current gain and duty cycle of three driving conditions applied to one variable-wavelength LED pixel within one display frame. This illustration shows how emission wavelength and brightness can be adjusted independently of one another in displays incorporating variable-wavelength LEDs. The longer the duty cycle (“on time”) of the driving signal, the higher the brightness of the emitted light. The higher the current density of the driving signal, the shorter the wavelength. FIG. 2 illustrates schematically how three different driving current magnitudes result in three different emission colours, while three different duty cycles result in three different luminances (brightnesses).

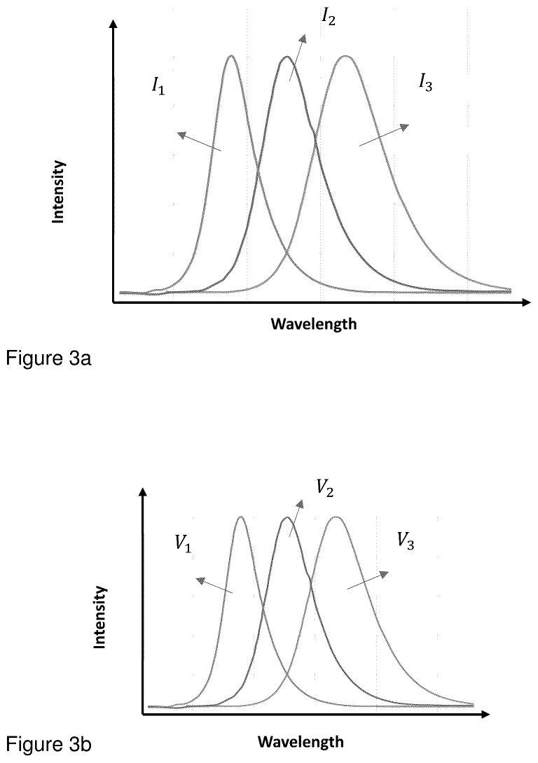

FIG. 3a schematically illustrates three emission peaks emitted by the same variable-wavelength LED pixel in response to three different driving currents I₁, I₂, I₃. Different magnitudes of driving current result in different peak emission wavelengths.

FIG. 3b schematically illustrates the alternative situation in which three emission peaks emitted by the same variable-wavelength LED pixel in response to three different driving voltages V₁, V₂, V₃. Different magnitudes of driving voltage result in different peak emission wavelengths.

Table 1 illustrates experimental data obtained for a variable-wavelength LED usable in the present invention. Table 1 shows measured conditions from 0.26″ array at 1% APL, in which Wavelength is in units of nm, and L is luminance.

TABLE 1

| Wavelength | FWHM/nm | L/cd/m\hat{ }2 |
|---|---|---|
| 466 | 50 | 1,000,473 |
| 482 | 50 | 880,927 |
| 515 | 50 | 964,512 |
| 517 | 50 | 725,799 |
| 529 | 50 | 429,071 |
| 533 | 50 | 299,851 |
| 545 | 50 | 113,520 |
| 578 | 50 | 12,082 |
| 595 | 50 | 3,264 |
| 616 | 50 | 596 |
| 639 | 50 | 68 |

This shows that the variable-wavelength LEDs emit longer wavelengths at much lower luminances than shorter wavelengths. The low brightness of longer-wavelength primaries can become a limiting factor when high display brightness is desired.

When driving a display comprising a variable-wavelength LED, even though the LED can be driven to emit all of these wavelengths, it is advantageous to calibrate the display device by picking a white-balance condition so that the relative luminances of the primaries can be set.

In one example embodiment, a set of three primary emission wavelengths is selected to be red, green and blue at 639 nm, 533 nm and 466 nm respectively.

In order for the output signal formed from a combination of these three primaries to make D65 white, the luminances of the red/green/blue primaries must be set in the ratio 1.6:3.6:1 respectively

In order to maximise the brightness of the red primary, the duty cycle of the driving signal for the red primary is set to 100% at 639 nm. This results in the red primary emitting 639 nm with a luminance of 68 cd/m².

The luminances required from green and blue primaries in order to meet the required colour-balance ratio, are calculated as shown in Table 2. Knowing the required luminances for these primaries, duty cycles of the driving signals for the green and blue primaries are computed to meet the white point condition.

The duty cycles for the other wavelengths are a free parameter and are calculated by interpolation.

TABLE 2

| | | | | L/cd/m\hat{ }2 after |
|---|---|---|---|---|
| Wavelength | FWHM/nm | L/cd/m\hat{ }2 | Duty cycle | duty cycle |
| 466 | 50 | 1,000,473 | 0.00% | 42 |
| 482 | 50 | 880,927 | 0.01% | 69 |
| 515 | 50 | 964,512 | 0.01% | 124 |
| 517 | 50 | 725,799 | 0.02% | 127 |
| 529 | 50 | 429,071 | 0.03% | 147 |
| 533 | 50 | 299,851 | 0.05% | 154 |
| 545 | 50 | 113,520 | 0.13% | 144 |
| 578 | 50 | 12,082 | 0.98% | 118 |
| 595 | 50 | 3,264 | 3.19% | 104 |
| 616 | 50 | 596 | 14.60% | 87 |
| 639 | 50 | 68 | 100.00% | 68 |

Now we have wavelengths (i.e. chromaticity coordinates) and luminances for all wavelengths in the set.

For this data set, the D65 white-balanced brightness is 264 cd/m².

This is limited by the brightness at the longest wavelength to be used as a primary emission wavelength, where the duty cycle is 100%.

The blue duty cycles are very short (at or close to 0%), as even with the duty cycle of the red driving condition at 100% duty cycle, the inherent low brightness of the long-wavelength red emission means that in order to fulfil this luminance ratio, the green and blue driving duty cycles must be made very short. In the case of the shortest primary wavelength, blue, in order to give a blue luminance that will balance with the red luminance, the blue duty cycle must be close to zero.

If the duration of pulse width modulation (the duty cycles) of the driving conditions are too short for blue and green primary emission wavelengths, the least significant bit LSB (ie. the emission wavelength that requires the shortest duty cycle) time for PWM will be too short to be achieved. MicroLED inherited capacitance will also cause poor performance in low grayscales.

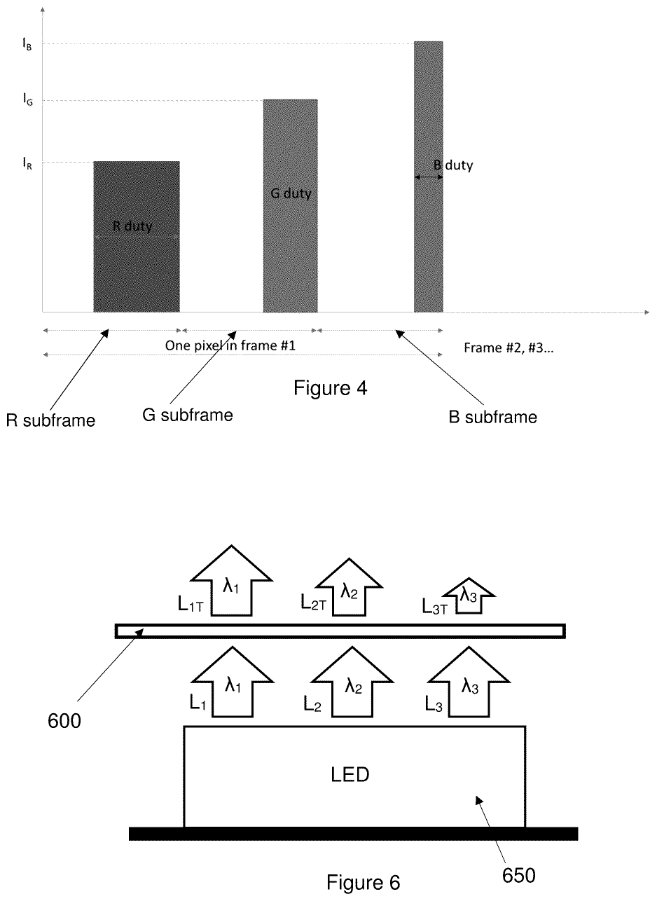

FIG. 4 illustrates an exemplary field-sequential driving sequence in which R, G and B driving conditions are supplied to a variable-wavelength LEDs as separate pulses of driving currents I_{R}, I_{G}, I_{B} supplied in three sequential subframes within a single display frame. As explained above, in order to balance the brightnesses of the three primaries, the duty cycles of the G and B driving pulses are shorter (the pulse-widths are narrower) than that of the R driving pulse which drives the LED to emit the red primary emission wavelength. In reality, the order and the durations of subframes may vary.

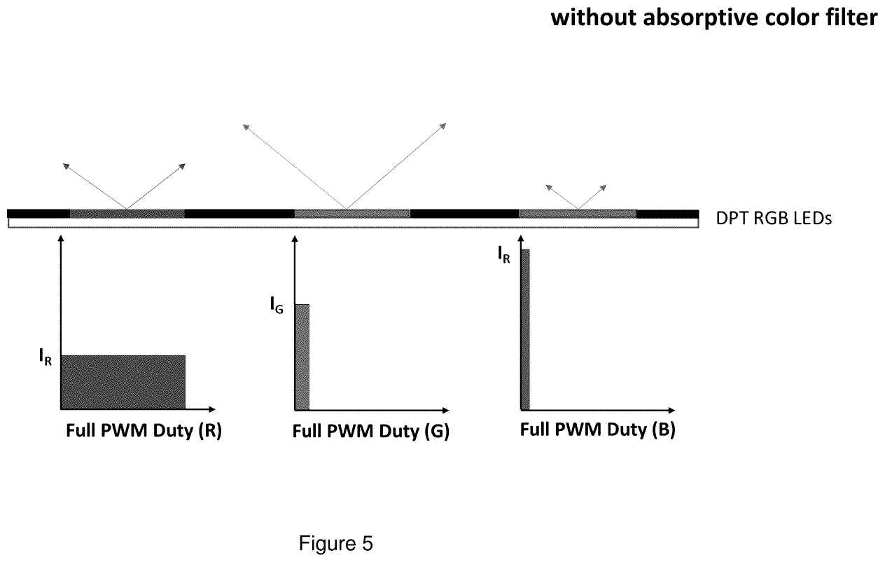

FIG. 5 provides a schematic illustration of the relative luminances of the R, G and B primary emission wavelengths which are required in order for the output signal to be perceived as D65 white light. In order to achieve this, the B duty cycle must be made very short, while R duty cycle is maintained at 100%.

The present invention provides a solution to the problem of overly-short duty cycles for short primary wavelengths such as B, by incorporating an absorptive colour filter into the display device in a position between the LED and the outlet of the device which is seen by a viewer.

FIG. 6 illustrates a display device according to the present invention, with absorptive colour filter 600 positioned over a variable-wavelength LED pixel 650 which is driveable to emit light at three primary emission wavelengths, λ₁, λ₂ and λ₃.

In this example, λ₁ is the shortest of the primary emission wavelengths, and is preferably a red wavelength, while λ₂ is a longer primary emission wavelength such as a green wavelength, and λ₃ is the longest primary emission wavelength such as a blue wavelength.

In order to compensate for the inherently-higher brightness of green and blue emission from the LED 650, the absorptive colour filter 600 is configured to absorb a proportion of light which has wavelength λ₂, and to emit an even higher proportion of light which has wavelength λ₃.

The filter 600 may alternatively be provided as two filters 600, one of which absorbs light with wavelength λ₂, and the other of which absorbs light with wavelength λ₃.

As it is desirable to transmit as much as possible of the short-wavelength λ₁ out of the device, the absorptive filter 600 is designed not to absorb light with wavelength λ₁.

In use, when a first driving condition is supplied to the LED 650, the LED emits light with the first primary wavelength λ₁. The emitted light has a first luminance L₁ which depends on the length of the first duty cycle for which the first driving condition is supplied to the LED.

As the absorptive filter 600 is configured not to absorb any light at wavelength λ₁, this emitted light is transmitted through the filter 600 at or close to 100% transmission, so that the first transmitted luminance L_{1T} of light exiting the display device after passing through the filter is close to or equal to the first luminance.

When a second driving condition is supplied to the LED 650, the LED emits light with the second primary wavelength λ₂. The emitted light has a second luminance L₂ which depends on the length of the second duty cycle for which the second driving condition is supplied to the LED. As the absorptive filter 600 is configured to absorb a proportion of light at wavelength λ₂, this emitted light is transmitted through the filter 600 at less than 100% transmission. This means that the second transmitted luminance L_{2T} of the light exiting the display device after passing through the filter is less than the second luminance L₂.

When a third driving condition is supplied to the LED 650, the LED emits light with the third primary wavelength λ₂. The emitted light has a third luminance L₃ which depends on the length of the third duty cycle for which the third driving condition is supplied to the LED. As the absorptive filter 600 is configured to absorb a high proportion of light at wavelength λ₃, this emitted light is transmitted through the filter 600 at considerably less than 100% transmission. This means that the third transmitted luminance L_{3T} of the light exiting the display device after passing through the filter is much lower than the third luminance L₃.

The use of the absorptive filter 600 addresses the problem of overly-short duty cycles for shorter, brighter emission wavelengths, by providing a wavelength-specific absorptive colour filter which reduces the transmitted luminance of the green and blue emission wavelengths of the variable-wavelength LED, without reducing the transmitted luminance of the red primary emission wavelength. The attenuation of the green and blue wavelengths by the absorptive colour filter allows longer duty cycles to be used to drive the green and blue emission wavelengths.

Thanks to the absorptive colour filter reducing the brightness of the transmitted green/blue light, instead of having to use very short duty cycles to create suitable green and blue luminances, longer and more practical duty cycles may be used for green and blue emission. These longer green and blue duty cycles causes the green and blue emission wavelengths to be emitted with luminances which are higher than desired for the output signal, but the absorptive colour filter counteracts this by partially absorbing the light at these primary wavelengths, and reducing the brightness of that light to transmitted luminances which are desired for the green/blue components of the output signal.

As a viewer observing the display device perceives an output signal which is the combination of the emitted wavelengths transmitted through the filter, it is the transmitted luminances of the first and second emission wavelengths which combine to create the perceived output signal. The absorptive colour filter may thus be designed to absorb a desired proportion of light at the second and third primary emission wavelengths, so that the transmitted first, second and third luminances fulfil whatever brightness-balance ratio is required for the output signal.

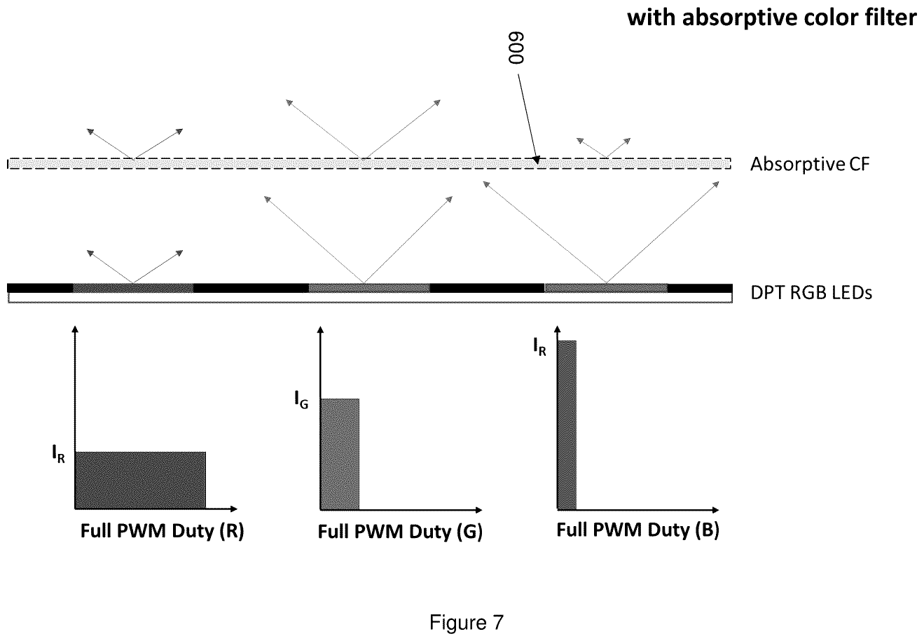

FIG. 7 illustrates the same driving currents and RGB primary emission wavelengths as FIG. 5, but with an absorptive colour filter 600 positioned between the variable-wavelength LED(s) and the outlet of the display device. As the filter 600 absorbs proportions of the green and blue emitted light, the green and blue duty cycles can be made longer relative to FIG. 5, and thus easier to control precisely. The absorptive filter 600 compensates for these longer green and blue duty cycles and absorbs some of the additional light emitted at those wavelengths, so that the output signal transmitted out of the filter 600 has the same colour- and brightness-balance as that produced in FIG. 5.

For example the transmitted wavelengths and luminances may combine to produce D65 white light in both scenarios, with the longer duty cycles in FIG. 7 making this embodiment more practical to drive.

A variety of absorptive filter types used in photography, optical instrument and illumination devices may be suitable for use in the present invention.

The absorptive colour filter 600 can be made from glass, plastic or film substrates by utilizing the material's inherent absorption or transmission properties. Absorptive colour filters can be formed from combinations of the semiconductor thin film materials.

Suitable filters may be provided as longpass, bandpass and lowpass filters, depending on the wavelengths to be absorbed.

The wavelengths absorbed by a filter may depend on the thickness of absorbing layers in the filter. By controlling the thickness of the material in the filter, precise filtering across large bandwidths can be achieved.

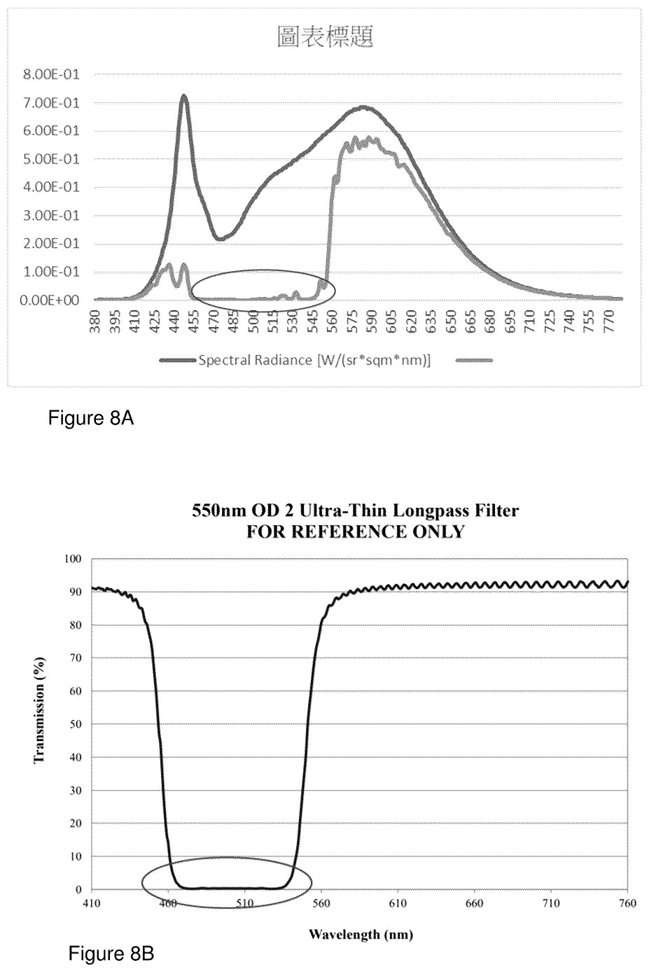

FIG. 8A shows experimental results showing the transmitted luminances measured when testing an embodiment of the invention with an off-the-shelf ultra-thin longpass filter #35124 available from Edmund Optics. FIG. 8B illustrates the expected absorption band of this filter.

A DPT® variable-wavelength LED by Poro Technologies Ltd was driven to emit white light from a combination of three primary emission wavelengths of 650 nm, 560 nm and 460 nm, and the transmission of wavelengths 650 nm, 560 nm and 460 nm by the absorptive filter was found to be around 92%, 50% and 10% respectively.

In a particularly preferred embodiment of the present invention, the display device comprises one or more absorptive colour filters which transmit green and blue primary emission wavelengths in a particular ratio of % absorption. Preferably, for example, the filter is configured to transmit green and blue filters in the relative proportions required for emission of a white D65 output signal. This may be achieved using a customized filter configured to transmit the desired proportions of these wavelengths, or by stacking a plurality of absorptive filters having different absorption bands.

The display device of the present invention is preferably calibrated using a method of calibration which involves driving the variable-wavelength LED with a first driving condition for a first duty cycle to emit a first emission wavelength λ₁ of the device, with a first luminance L₁. The variable-wavelength LED is then driven with a second driving condition for a second duty cycle to emit a second emission wavelength λ₂ which is shorter than the first emission wavelength, with a second luminance L₂. The variable-wavelength LED is then driven with a third driving condition for a third duty cycle to emit a third emission wavelength λ₃ which is shorter than the first emission wavelength, with a third luminance L₃.

The absorptive colour filter is configured not to attenuate the first emission wavelength, so light emitted at the first emission wavelength is transmitted out of the absorptive colour filter with a first transmitted luminance L_{1T}.

The absorptive colour filter is configured to attenuate the second luminance L₂ of the second emission wavelength so that the second emission wavelength is transmitted out of the absorptive colour filter with a second transmitted luminance L_{2T}, wherein L_{2T}<L₂. The absorptive colour filter is further configured to attenuate the third luminance L₃ of the third emission wavelength, so that the third emission wavelength is transmitted out of the absorptive colour filter with a third transmitted luminance L_{3T}, wherein L_{3T}<L₃.

In order to calibrate the display device, the first duty cycle (the duty cycle driving the shortest of the primary emission wavelengths used to control the device) is set at 100%. The second and third duty cycles are given shorter durations than the first duty cycle, and the durations of the second and third duty cycles are set to calibrated second and third duty cycles respectively, at which the first, second and third emission wavelengths λ₁, λ₂, λ₃ and the transmitted first, second and third transmitted luminances L_{1T}, L_{2T}, L_{3T} are complementary and sum to a standard illuminant point.

In use, a preferred three-primary embodiment of the display device of the present invention is driven by driving the variable-wavelength LED to emit the first, second and third primary emission wavelengths in the proportions required to form an output signal with a desired output chromaticity and output luminance. The output chromaticity of the output signal may be varied by altering the relative proportions of the three primary wavelengths which are emitted by the LED during a display frame. The output luminance of the output signal may be varied by altering the durations of the duty cycles during which the driving conditions are provided to the variable-wavelength LED.

In particularly preferred embodiments of the present invention, the display device comprises a plurality of variable-wavelength LEDs forming a pixel matrix. Each variable-wavelength LED is preferably separately driveable, and may be separately calibrated and driven using the methods of the present invention.

### Variable-Wavelength LEDs

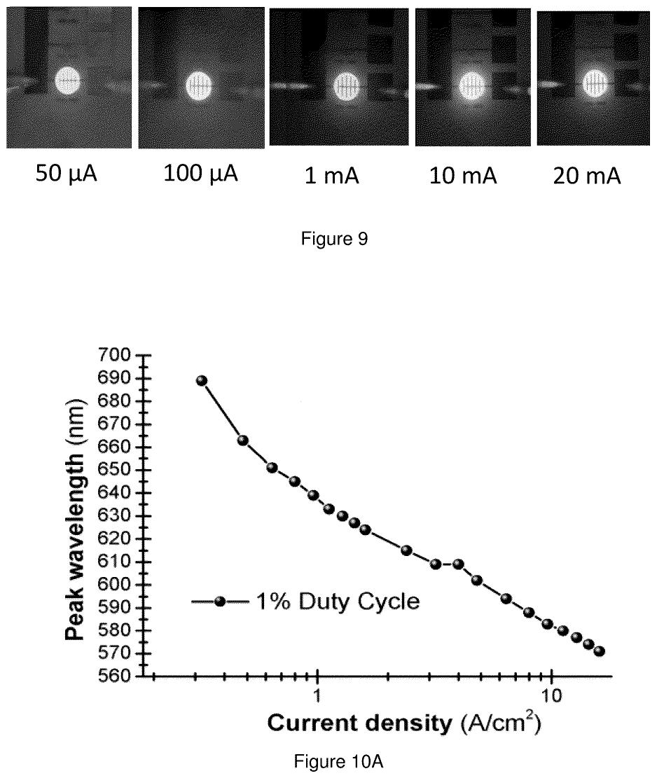

Variable-wavelength LEDs driveable in the present invention are described further above and below with reference to FIGS. 9-15E.

In a particularly preferred embodiment of the present invention, the device epitaxial structure from which all of the device mesas are formed is a variable-wavelength LED epitaxial structure. Particularly advantageously, a single variable-wavelength LED epitaxial structure may be grown over a porous region of III-nitride material at wafer-scale to form a monolithic device wafer comprising an array of variable-wavelength LEDs which are formed from the same materials.

An entire wafer-scale device structure may be formed during a single epitaxial growth process, and then the method of the present invention may be used to process the resulting device wafer into an opto-electronic device in which each separate device mesa acts as a separate variable-wavelength LED.

This provides a large number of possibilities for a display device, as the “colour” (the peak emission wavelength) emitted by each LED can be controlled by controlling the driving current density provided to that particular LED mesa in use.

The driving circuit may thus be configured to drive the variable-wavelength LEDs in the device in a variety of ways depending on the desired result:
Each variable-wavelength LED in the device may be dynamically driven by the driving circuit, with each variable-wavelength LED receiving a drive current density the magnitude of which varies in real time during a display frame, so that the same variable-wavelength LED may be controlled to emit a plurality of different wavelengths during a single display frame.
Each variable-wavelength LED may be driven by the driving circuit with a fixed driving current density, so that the variable-wavelength LEDs behave as fixed-wavelength emitters in use. However, the driving circuit may be configured to provide driving current densities of different magnitudes to different variable-wavelength LEDs in the device. Even though the different variable-wavelength LEDs are formed from the same epitaxy and have the same device structure, the different driving current densities control different device mesas to emit different fixed peak emission wavelengths. Thus by providing different fixed drive conditions to different device mesas, a multi-colour display may be provided from a single device epitaxy.
A mixture of these two options may also be provided, with the driving circuit being configured to control some device mesas in the device dynamically, and to control other device mesas as fixed-wavelength emitters by providing a fixed driving current to those mesas.

During manufacturing, the size, shape and position of the variable-wavelength LEDs may be controlled by controlling the size, shape, depth and position of trenches etched into the device wafer.

By forming all of the separate device mesas from a single wafer epitaxy, it is possible to eliminate many of the time-consuming, low-yield and expensive processing steps required for device integration in the prior art.

In preferred embodiments of the present invention, the driving circuit and some or all of the variable-wavelength LEDs are preferably configured to receive a variable-magnitude supply of driving current from the driving circuit, so that the magnitude of the driving current to each variable-wavelength LED is variable. By varying the magnitude of the driving current to a variable-wavelength LED, the peak emission wavelength of that LED can be varied as the display device is used. The driving current provided to each variable-wavelength LED may be individually controllable, so that the peak emission wavelength of each variable-wavelength LED in the display may be controlled and varied individually. Alternatively, the device and the driving circuit may be configured so that the same driving conditions are provided to a group of variable-wavelength LEDs simultaneously, so that all of the variable-wavelength LEDs in that group emit light at the same peak emission wavelength when the driving current is on, and the peak emission wavelength of the entire group can be varied by varying the magnitude of the driving current.

In alternative embodiments, the driving circuit may be configured to provide a fixed-magnitude (i.e. non-variable) driving current, which is either on or off, to some or all of the variable-wavelength LEDs in the display device. When the fixed driving current is on, those variable-wavelength LEDs will behave as conventional LEDs, and emit at a single peak emission wavelength determined by the driving conditions provided to the LEDs. Thus variable-wavelength LEDs which are configured to receive a fixed-magnitude driving current may be used as fixed-emission-wavelength LEDs in the display device.

Preferably the driving circuit is configured to control at least one subpixel of each pixel as a dynamic variable-wavelength LED, the peak emission wavelength of which may be varied within a single display frame.

The driving circuit may be configured to separately control the driving current provided to each of the plurality of LEDs, so that each of the plurality of LEDs is individually driveable.

The driving circuit may be configured to provide a plurality of different driving currents to the plurality of LEDs, so that separate LEDs are driveable to emit at different peak emission wavelengths in response to the different driving currents.

Alternatively, the driving circuit may be configured to separately control a groups of two or more LEDs, so that each LED in a group emits at the same peak emission wavelength. The driving circuit may be configured to provide different driving currents to different groups of LEDs, so that separate groups of LEDs are driveable to emit at different peak emission wavelengths in response to the different driving currents.

FIG. 9 is a series of five EL images of the same variable-wavelength MicroLED InGaN pixel being driven at different currents in constant wave mode (CW), showing five different colours of emission. In the left-hand image, the micro-LED emission colour is seen to be red at a driving current of 50 μA. In the second image from the left, the micro-LED emission colour is seen to be red-orange at a driving current of 100 μA. In the third image from the left, the micro-LED emission colour is seen to be orange at a driving current of 1 mA. In the fourth image from the left, the micro-LED emission colour is seen to be yellow-green at a driving current of 10 mA. In the right-hand image, the micro-LED emission colour is seen to be green at a driving current of 20 mA.

By varying the driving current between 50 μA to 20 mA, the same micro-LED is therefore capable of emitting at wavelengths ranging from red to green. The spectral width of this emission wavelength range is on the order of 90 nm (from around 570 nm to around 660 nm). This is a far greater range of emission wavelengths than has ever been achievable with a single LED in the prior art.

FIG. 10A is an emission wavelength vs current density plot for a 25 μm×25 μm InGaN LED pixel array (100×100 array, containing 10,000 pixels) driven in pulsed mode with a 100 μs pulse at 1% duty cycle. FIG. 10B is an emission wavelength vs current density plot for a 30 μm×30 μm InGaN LED pixel array (100×100 array, containing 10,000 pixels) driven in pulsed mode with a 100 μs pulse at 1% duty cycle.

Both of these plots show the controllability of the peak emission wavelength with a pulse driven power supply. In particular, the wavelength is linearly dependent on the current density (plotted on a logarithmic scale). This linearity can equally be manipulated when driving with a pulsed voltage power supply. The variable emission wavelengths of the LED can therefore be controlled with either voltage or current driving schemes in either CW or pulsed mode, all of which are standard ways of display driver IC.

This linear relationship between the driving current density and the resulting emission wavelength is highly advantageous for the purposes of LED display design, as it enables accurate control of the emission wavelengths by varying the current density of the power supply.

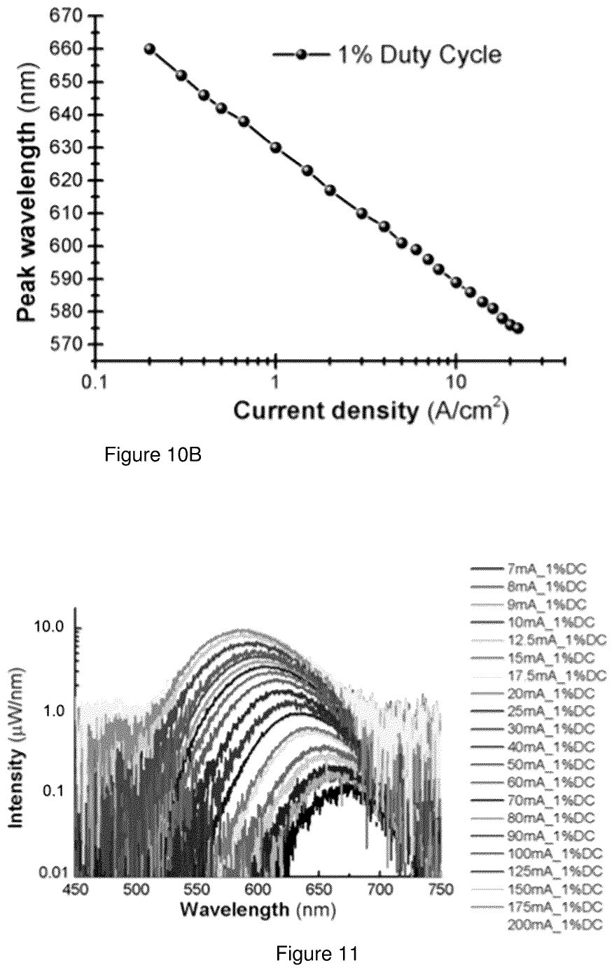

FIG. 11 is a plot of intensity vs wavelength for a variable-wavelength InGaN LED driven at different DC currents. The power supply is operated in pulsed driving mode with a 100 us pulse at 1% duty cycle.

FIG. 11 again reflects a gradual, continuous transition of the peak emission wavelength of the LED as the current of the power supply is varied. At a driving current of 200 mA, the peak emission wavelength is around 575 nm, with an intensity of around 10 μW/nm. As the driving current is reduced, however, the peak emission wavelength moves gradually to longer wavelengths, and to lower emission intensities. When the driving current reaches 7 mA, the peak emission wavelength is approximately 675 nm, with an intensity of around 0.1 μW/nm.

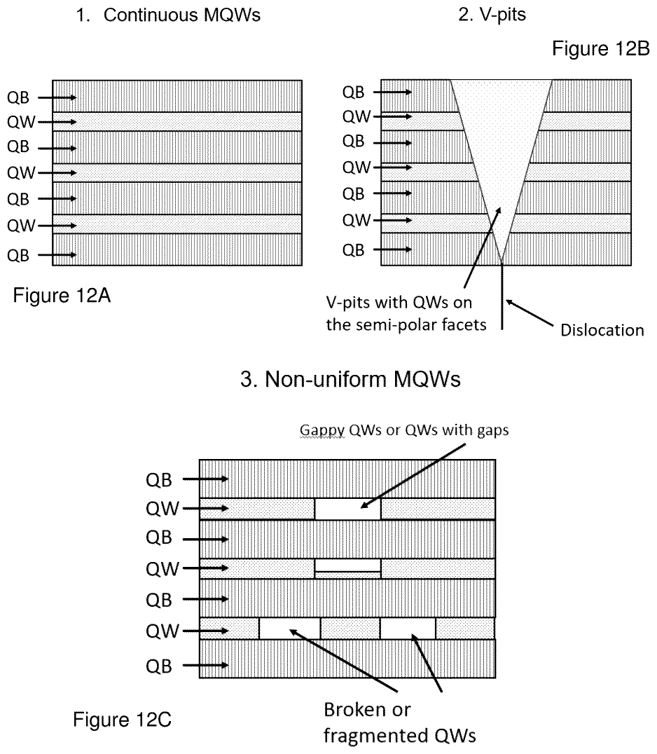

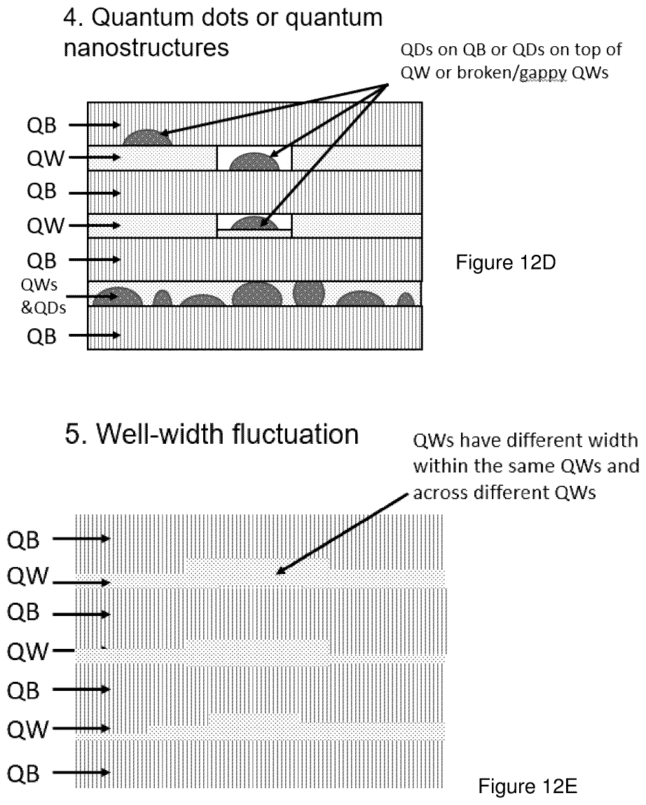

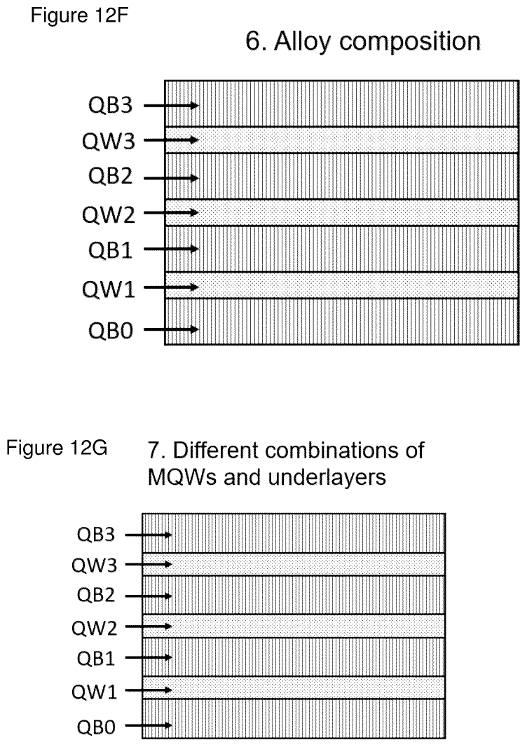

FIGS. 12A-G illustrate alternative embodiments of light-emitting regions of variable-wavelength LEDs which can be used as semiconductor devices in embodiments of the present invention.

Examples of MQWs:
1. Continuous MQWs
2. V-pits
3. Broken QWs, gappy QWs, fragmented QWs
4. QDs
5. Well-width fluctuation
6. Alloy composition
7. Different combinations of MQWs and underlayers

These structural characteristics can be identified and examined by standard material characterisation techniques, such as cross-sectional transmission electron microscopy (TEM), X-ray diffraction (XRD), Energy Dispersive X-ray Spectroscopy (EDX or EDS), 3D atom probe (3DAP).

FIG. 12A shows a continuous MQW light-emitting region of an LED, in which three identical QWs are provided between four identical quantum barriers (QBs).

FIG. 12B shows the continuous MQW of FIG. 12A, with a V-shaped pit propagating through the light-emitting region. The v-shaped pit terminates in a threading dislocation, and has QWs on its semi-polar facets.

FIG. 12C shows a MQW in which the QW layers comprise discontinuities or gaps in the semiconductor material.

FIG. 12D shows a MQW in which quantum dots (QDs) create non-uniformities in the MQW. QDs may be provided on or in the QB or QW layers, for example in gaps in the QW structure.

FIG. 12E shows a MQW with well-width fluctuation, in which the thicknesses of the QW layers are not uniform across the light-emitting region. The QWs may have different widths from each other, and also varying widths within a single QW.

FIG. 12F shows a MQW with fluctuations in alloy composition in the light-emitting region. The compositions of the QBs and the QWs differ from layer to layer. In particular, the indium In % composition is varying within the same QWs, i.e. in QW2, In % is varying between 10-12% or 10-15%, or 10-25%, or 10-35%.

FIG. 12G shows a MQW containing different combinations of MQWs and underlayers. In % composition is different across different QWs. For example In % in QW1 is 15%, In % in QW2 is 25%, and In % in QW3 is 30%. In embodiments of the present invention, the lower In % QW is preferably positioned at the bottom of the MQW, due to its strain and thermal effect, while the high In % QWs is preferred to be on the top. In a preferred embodiment, for example, QW1 is a blue emitting QW, QW2 is a green emitting QW, QW3 is a red emitting QW.

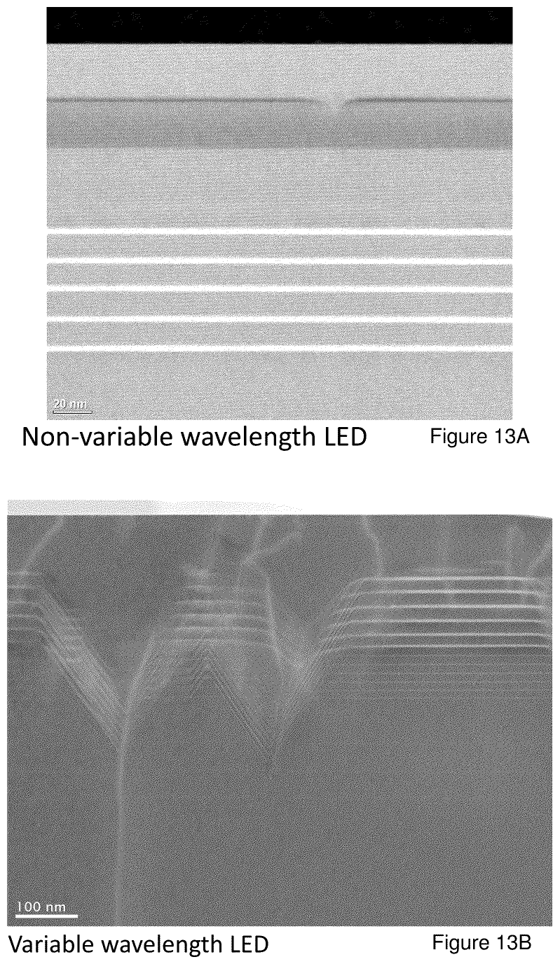

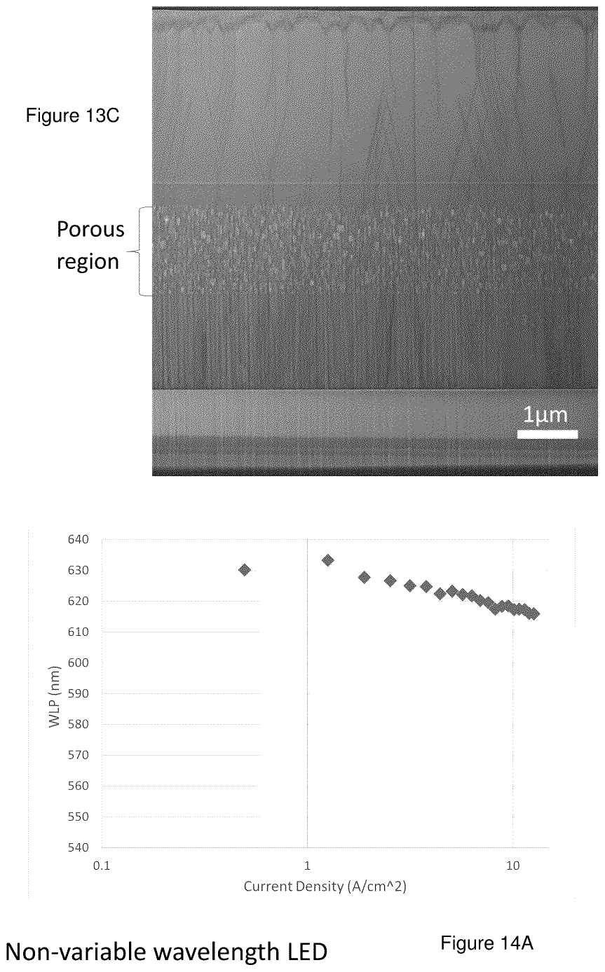

FIG. 13A is a TEM image of a cross-section of a conventional non-variable-wavelength LED. In this non-variable-wavelength LED, the MQWs are uniform and smooth in both upper and lower interface (5 MQWs shown here).

FIGS. 13B and 13C are TEM images a variable-wavelength LED comprising v-shaped pits, usable in an embodiment of the present invention. In this variable-wavelength LED, the MQWs are non-uniform. This non-uniformity can be induced by various methods, one example is v-pits and the semi-polar facets which would incorporate more indium and thinner QWs. Another example is also shown in FIG. 7B, that the MQWs are not uniform, in terms of broken QWs, discontinuous QWs, fragmented QWs, QWs with well-width or In composition fluctuation.

FIG. 13C shows a cross section of the variable-wavelength LED of FIG. 13B, showing a porous region and a light-emitting region comprising a plurality of v-shaped pits, usable in a preferred embodiment of the present invention.

In this structure, the light-emitting region contains multiple emission wavelength regions that are deliberately introduced such as multiple types of QW region with v-shaped pits extending through the light-emitting region.

V-shaped pits (V-pits) are actually hexagonal pits looking from the above, v-shape is when looking at the cross-section. V-pits can be initialize at each site of dislocations under special epitaxy growth conditions during the growth of InGaN, GaN, InGaN/InGaN superlattice, or InGaN/GaN superlattice structures underlying the MQWs, such as low growth temperature (e.g. <1000° C., or <900° C., or <800° C., or <700° C.) and nitrogen ambient.

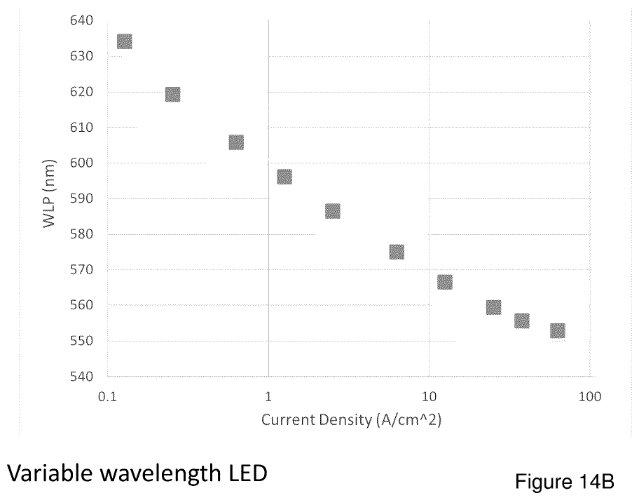

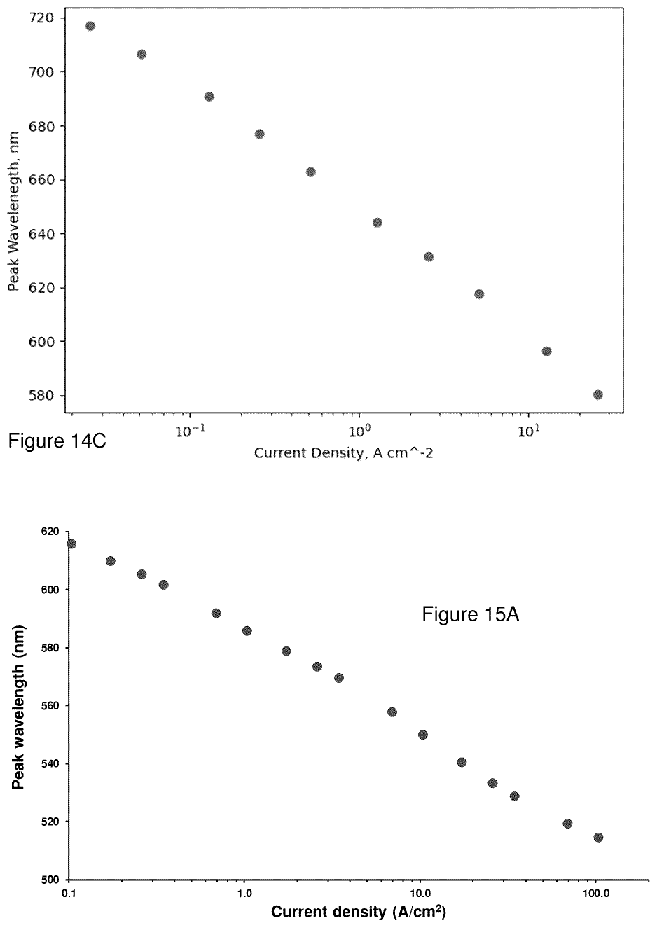

FIG. 14A is a graph of peak emission wavelength vs driving current density for a conventional non-variable wavelength LED. By varying the driving current density applied to the LED, the emission wavelength can be slightly varied, across an emission wavelength range of around 15 nm.

FIG. 14B is a graph of peak emission wavelength vs driving current density for a variable-wavelength LED usable as a first or second semiconductor device in embodiments of the present invention. In the variable-wavelength LED, varying the current density of the driving power supply creates a much larger variation in the peak emission wavelengths (WLP) emitted by the LED. In this embodiment, varying the driving current density between roughly 0.1 and 100 A/cm² varies the peak emission wavelength from around 635 nm to around 550 nm—an emission wavelength range of around 85 nm.

FIG. 14C is a graph of peak emission wavelength vs driving current density for a variable-wavelength LED according to another embodiment of the present invention. In this embodiment, varying the driving current density varies the peak emission wavelength from around 720 nm to around 580 nm—an emission wavelength range of around 140 nm.

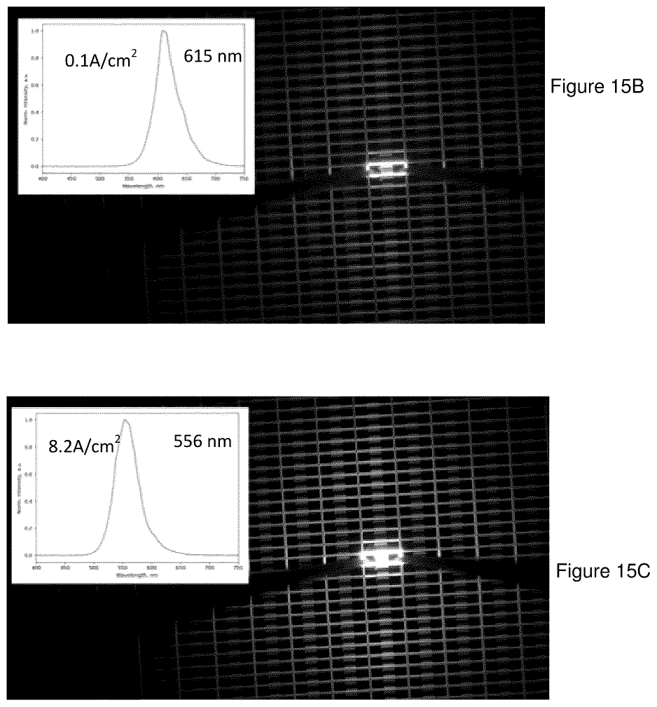

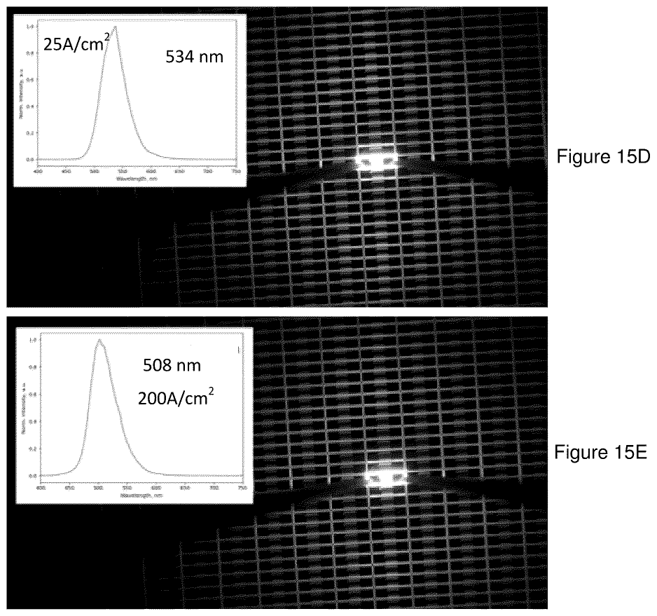

FIG. 15A is a graph of peak emission wavelength vs driving current density for another variable-wavelength LED according to the present invention. In this embodiment, varying the driving current density between roughly 0.1 and 200 A/cm² varies the peak emission wavelength from 615 nm to 508 nm—an emission wavelength range of around 100 nm. The data for this graph only goes to 514.5 nm due to a limitation on the testing capabilities. The current density for 508 nm is therefore estimated. However, the obtainable range of emission wavelengths can be pushed either way significantly.

FIGS. 15B-D are photographs of the variable-wavelength LED of FIG. 13A, showing the same variable-wavelength LED emitting at four different wavelengths across its emission wavelength range. The inset emission spectra show the different peak emission wavelengths at different driving current densities. This shows the same variable-wavelength LED emitting at peak emission wavelengths in the orange (615 nm), yellow (556 nm), green (534 nm) and blue (508 nm) in response to different driving current densities.

1. A display device comprising:
a variable-wavelength LED, the variable-wavelength LED being a pixel of the device, or one of a plurality of subpixels of a device pixel; and
an absorptive colour filter, the absorptive colour filter being positioned between the variable-wavelength LED and an outlet of the display device, such that light emitted by the variable-wavelength LED passes through the absorptive colour filter before passing out of the outlet of the display device,
in which the variable-wavelength LED, or a second LED subpixel, is driveable to emit light at a first emission wavelength in response to a first electrical driving condition, and in which the variable-wavelength LED is driveable to emit light at a second emission wavelength in response to a second electrical driving condition;
in which the second emission wavelength is shorter than the first emission wavelength, and
in which the absorptive colour filter is configured to attenuate the luminance of light emitted at the second emission wavelength.

2. The display device of claim 1, in which the display device is a subpixellated display, in which the variable-wavelength LED is a first subpixel which is driveable to emit light at the second emission wavelength, and in which the display comprises a second LED subpixel which is driveable to emit light at the first emission wavelength, the first and second subpixels being subpixels of the same display pixel, and the first and second subpixels being driveable independently of one another.

3. The display device of claim 2, in which the second LED subpixel is a second variable-wavelength LED subpixel.

4. The display device of claim 1, in which the variable-wavelength LED is a pixel of the device, wherein the variable-wavelength LED is driveable to emit light at the first emission wavelength in response to the first electrical driving condition provided to the variable-wavelength LED, and wherein the variable-wavelength LED is driveable to emit light at the second emission wavelength in response to a second electrical driving condition provided to the variable-wavelength LED.

5. The display device of any preceding claim, in which the absorptive colour filter is configured so that in use, light emitted at the first emission wavelength has a first luminance L₁ prior to transmission through the absorptive colour filter, and a first transmitted luminance L_{1T} after transmission through the absorptive colour filter, and light emitted at the second emission wavelength has a second luminance L₂ prior to transmission through the absorptive colour filter, and a reduced second transmitted luminance L_{2T} after transmission through the absorptive colour filter.

6. The display device of any preceding claim, in which the absorptive colour filter is configured to reduce, or modulate, the luminance of light having the second emission wavelength, so that in use, light emitted at the second emission wavelength has a second luminance L₂ prior to transmission through the absorptive colour filter, and a reduced second transmitted luminance L_{2T} after transmission through the absorptive colour filter, such that L_{2T}<L₂.

7. The display device of any preceding claim, in which the absorptive colour filter is configured not to reduce the luminance of light having the first emission wavelength, so that the magnitude of the first transmitted luminance L_{1T} is at least 90%, or at least 92%, or at least 95%, or at least 98% of the magnitude of the first luminance L₁.

8. The display device of any preceding claim, in which the absorptive colour filter is configured to absorb light emitted at the second emission wavelength to a greater degree than light emitted at the first emission wavelength, so that the ratio of L_{2T}:L_{1T} is lower than the ratio of L₂:L₁.

9. The display device of any preceding claim, in which the variable-wavelength LED is controllable to emit light at two or more selected primary emission wavelengths, such that in use the light transmitted out of the outlet of the display device during a display frame forms an observed signal which is the temporal combination of the primary emission wavelengths emitted by the variable-wavelength LED during the display frame.

10. The display device of claim 9, in which the first and second emission wavelengths are first and second primary emission wavelengths.

11. The display device of any preceding claim, in which the display device comprises a controller programmed to drive the variable-wavelength LED to emit the first and second emission wavelengths in response to first and second respective driving conditions, the first and second emission wavelengths being wavelengths within the emission wavelength range of the variable-wavelength LED.

12. The display device of claim 11, in which the controller is programmed to drive the variable-wavelength LED in a field-sequential mode to emit the first and second emission wavelengths within discrete subframes of the same display frame.

13. The display device of any preceding claim, in which the first driving condition is a first current density, and the second driving condition is a second current density greater in magnitude than the first current density.

14. The display device of any preceding claim, in which the first emission wavelength is a red emission wavelength of above 595 nm or above 630 nm, preferably in which the first emission wavelength is between 595 nm and 700 nm, or between 610 nm and 680 nm, preferably between 625 nm and 670 nm.

15. The display device of any preceding claim, in which the second emission wavelength is less than 595 nm.

16. The display device of any preceding claim, in which the second emission wavelength is a green emission wavelength of between 500 nm and 590 nm, or between 510 nm and 580 nm, preferably between 525 nm and 570 nm, or in which the second emission wavelength is a blue emission wavelength of below 495 nm, preferably in which the second emission wavelength is between 400 nm and 490 nm, or between 410 nm and 480 nm, preferably between 430 nm and 470 nm.

17. The display device of any preceding claim, in which the first and second emission wavelengths are at least 40 nm apart, or at least 50 nm apart within the emission wavelength range of the variable-wavelength LED.

18. The display device of any preceding claim, in which the display comprises a plurality of absorptive colour filters, each absorptive colour filter being configured to attenuate the luminance of light emitted at a respective emission wavelength.

19. The display device of any preceding claim, in which the variable-wavelength LED is driveable to emit light at a third emission wavelength in response to a third electrical driving condition provided to the variable-wavelength LED, the third emission wavelength being shorter than the first emission wavelength, and the first, second and third emission wavelengths being within the emission wavelength range of the variable-wavelength LED.

20. The display device of claim 19, in in which the absorptive colour filter is configured to attenuate the luminance of light emitted at the third emission wavelength as well as the luminance of light emitted at the second emission wavelength.

21. The display device of claim 19 or 20, in in which the absorptive colour filter is a second-emission-wavelength-absorptive filter configured to modulate the luminance of the second emission wavelength, and in which the device comprises an additional third-emission-wavelength-absorptive filter which is configured to modulate the luminance of the third emission wavelength.

22. The display device of claim 19, 20 or 21, in which the absorptive colour filter is configured to reduce, or attenuate, the luminance of light having the third emission wavelength, so that in use, light emitted at the third emission wavelength has a third luminance L₃ prior to transmission through the absorptive colour filter, and a reduced third transmitted luminance L_{3T} after transmission through the absorptive colour filter.

23. The display device of any of claims 19 to 22, in which the first, second and third wavelengths are first, second and third primary emission wavelengths.

24. The display device of any of claims 19 to 23, in which the absorptive colour filter is configured to reduce the luminance of light emitted at the second emission wavelength, and to reduce the luminance of light emitted at the third emission wavelength, and in which the absorptive colour filter is configured not to reduce the luminance of light emitted at the first emission wavelength.

25. The display device of any of claims 19 to 24, in which the absorptive colour filter is configured to reduce the luminance of the light emitted by the variable-wavelength LED at the second and third emission wavelengths, and in which the absorptive colour filter is configured to reduce the luminance of the light emitted at the third emission wavelength by a different proportion than it reduces the luminance of light emitted at the second emission wavelength.

26. The display device of any of claims 19 to 25, in which the third emission wavelength is less than 595 nm, preferably less than 495 nm.

27. The display device of any of claims 19 to 26, in which the second emission wavelength is a green emission wavelength of between 500 nm and 590 nm, or between 510 nm and 580 nm, preferably between 525 nm and 570 nm, and in which the third emission wavelength is a blue emission wavelength of below 495 nm, preferably in which the third emission wavelength is between 400 nm and 490 nm, or between 410 nm and 480 nm, preferably between 430 nm and 470 nm.

28. The display device of any of claims 19 to 27, in which the first, second and third emission wavelengths are at least 40 nm apart, or at least 50 nm apart from one another within the emission wavelength range of the variable-wavelength LED, so that the highest and lowest of the first, second and third emission wavelengths are separated by at least 80 nm, or at least 100 nm.

29. The display device of any of claims 19 to 28, in which the absorptive colour filter is configured to attenuate the luminance of the second emission wavelength from a second luminance L₂, which is emitted by the variable-wavelength LED, to a second transmitted luminance L_{2T}, and to attenuate the luminance of the third emission wavelength from a third luminance L₃, which is emitted by the variable-wavelength LED, to a third transmitted luminance L_{3T}, so that the wavelengths and transmitted luminances of the first, second and third emission wavelengths are complementary and sum to a standard illuminant point.

30. The display device of any preceding claim, in which the absorptive colour filter is configured to attenuate the luminance of the second emission wavelength from a second luminance L₂, which is emitted by the variable-wavelength LED, to a transmitted second luminance L_{2T}, so that the wavelengths and transmitted luminances of the first and second emission wavelengths are complementary and sum to a standard illuminant point.

31. The display device of claim 29 or 30, in which the standard illuminant point is a white point, preferably in which the standard illuminant point is CIE standard illuminant point D65.

32. The display device of any preceding claim, in which the absorptive colour filter comprises a glass, plastic or semiconductor-film substrate.

33. The display device of any preceding claim, in which the absorptive colour filter is a longpass filter.

34. The display device of any of claims 1 to 32, in which the absorptive colour filter is a bandpass filter.

35. The display device of any of claims 1 to 32, in which the absorptive colour filter is a lowpass filter.

36. The display device of any preceding claim, in which the variable-wavelength LED has an emission wavelength range with a width of between 100 nm and 200 nm, or between 125 nm and 185 nm, or between 150 nm and 175 nm, in which the variable-wavelength LED is continuously controllable over the emission wavelength range by varying the electrical driving condition provided to the variable-wavelength LED.

37. The display device of any preceding claim, in which the emission wavelength range of the variable-wavelength LED extends from a lower limit, which is preferably below 500 nm or below 450 nm, to an upper limit, which is preferably above 595 nm or above 630 nm.

38. The display device of claim 37, In which the lower limit of the emission wavelength range is between 440 nm and 495 nm, or between 440 nm and 485 nm, preferably between 450 nm and 470 nm.

39. The display device of claim 37 or 38, in which the upper limit of the emission wavelength range is between 595 nm and 700 nm, or between 610 nm and 680 nm, preferably between 625 nm and 670 nm.

40. The display device of any preceding claim, in which the variable-wavelength LED has a FWHM of 50 nm or less, or 40 nm or less, or 30 nm or less, or 20 nm or less.

41. The display device of any preceding claim, comprising an array of variable-wavelength LEDs, each variable-wavelength LED being a pixel of the device, or one of a plurality of subpixels of a device pixel.

42. The display device of any preceding claim, in which the absorptive colour filter is positioned over a plurality of variable-wavelength LEDs between the variable-wavelength LEDs and an outlet of the display device, such that light emitted by the plurality of variable-wavelength LEDs passes through the absorptive colour filter before passing out of the outlet of the display device.

43. A method of calibrating a display device comprising a variable-wavelength LED, the variable-wavelength LED being a pixel of the device, or one of a plurality of subpixels of a device pixel, and an absorptive colour filter, the absorptive colour filter being positioned between the variable-wavelength LED and an outlet of the display device, such that light emitted by the variable-wavelength LED passes through the absorptive colour filter before passing out of the outlet of the display device,
the method comprising the steps of:
driving the variable-wavelength LED, or a second LED subpixel, with a first driving condition for a first duty cycle to emit a first emission wavelength λ₁, with a first luminance L₁, in which the first emission wavelength is transmitted out of the absorptive colour filter with a first transmitted luminance L_{1T};
driving the variable-wavelength LED with a second driving condition for a second duty cycle to emit a second emission wavelength λ₂, with a second luminance L₂, the second emission wavelength being shorter than the first emission wavelength;
in which the absorptive colour filter is configured to attenuate the second luminance L₂ of the second emission wavelength so that the second emission wavelength is transmitted out of the absorptive colour filter with a second transmitted luminance L_{2T}, wherein L_{2T}<L₂;
setting the second duty cycle to a shorter duration than the first duty cycle, and controlling the duration of the second duty cycle so that the first and second emission wavelengths λ₁, λ₂ and the first and second transmitted luminances L₁, L_{2T} are complementary and sum to a standard illuminant point.

44. The method of claim 43, in which the display device is a subpixellated display, in which the variable-wavelength LED is a first variable-wavelength subpixel, and in which the method comprises the steps of driving a second LED subpixel to emit light at the first emission wavelength, and driving the first variable-wavelength subpixel to emit light at the second emission wavelength.

45. The method of claim 43, in which the variable-wavelength LED is a pixel of the device, and wherein the method comprises the steps of driving the variable-wavelength LED with a first driving condition for a first duty cycle to emit a first emission wavelength λ₁ of the device, and driving the variable-wavelength LED with a second driving condition for a second duty cycle to emit a second emission wavelength λ₂.

46. The method of claim 43, 44 or 45, in which the duration of the second duty cycle is controlled to find a calibrated second duty cycle, at which the first and second emission wavelengths λ₁, λ₂ and the transmitted first and second luminances L_{1T}, L_{2T} are complementary and sum to the standard illuminant point.

47. The method of any of claims 43 to 46, in which the standard illuminant point is a white point, preferably in which the standard illuminant point is CIE standard illuminant point D65.

48. The method of any of claims 43 to 47, in which the first duty cycle is a 100% duty cycle.

49. The method of any of claims 43 to 48, in which the method comprises the step of selecting a set of two or more discrete primary emission wavelengths λ_{P} within an emission wavelength range of the variable-wavelength LED, the set of primary emission wavelengths corresponding to a set of two or more respective driving conditions; in which the first emission wavelength λ₁ is the longest of the selected primary emission wavelengths, and in which the second emission wavelength λ₂ is another of the selected primary emission wavelengths.

50. The method of any of claims 43 to 49, in which the step of controlling the duration of the second duty cycle controls the second transmitted luminance L_{2T} of the light emitted when the second driving condition is applied.

51. The method of any of claims 43 to 50, the method comprising the step of driving the variable-wavelength LED with a third driving condition for a third duty cycle to emit a third emission wavelength λ₃ of the device, with a third luminance L₃, the third emission wavelength being shorter than the first emission wavelength,
in which the absorptive colour filter is configured to attenuate the third luminance L₃ so that the third emission wavelength is transmitted out of the absorptive colour filter with a third transmitted luminance L_{3T}, wherein L_{3T}<L₃,
and in which the method comprises the step of setting the third duty cycle to a shorter duration than the first duty cycle, and controlling the duration of the third duty cycle so that the first, second and third emission wavelengths and the first, second and third transmitted luminances L_{1T}, L_{2T}, L_{3T} are complementary and sum to a standard illuminant point.

52. The method of claim 51, in which the second emission wavelength and the third emission wavelength are shorter than the first emission wavelength, and the second duty cycle and the third duty cycle are shorter than the first duty cycle.

53. The method of any of claims 43 to 52, comprising the step of using the first luminance L₁ as a reference luminance and the first duty cycle as a reference duty cycle, and setting the second and optionally third duty cycles to shorter durations than the first duty cycle so that the second and optionally third transmitted luminances fulfil, with the first transmitted luminance L_{1T}, a standard-illuminant point colour-mixing ratio at which the emission wavelengths and transmitted luminances of the first, second and optionally third emission wavelengths are complementary and sum to the standard illuminant point.

54. The method of any of claims 43 to 53, in which the variable-wavelength LED emits red light in response to the first driving condition, green light in response to the second driving condition, and blue light in response to the third driving condition.

55. The method of any of claims 43 to 54, comprising a step of selecting first, second and third primary emission wavelengths for driving the variable-wavelength LED.

56. The method of claim 55, in which the method comprises the step of selecting a set of three discrete primary emission wavelengths λ_{P} within the emission wavelength range of the variable-wavelength LED, the set of primary emission wavelengths corresponding to a set of three respective driving conditions; in which the first emission wavelength λ₁ is the longest of the selected primary emission wavelengths, and in which the second and third emission wavelengths λ₂, λ₃ are the other selected primary emission wavelengths.

57. The method of claim 55 or 56, comprising the step of looking up, or calculating, a standard-illuminant point colour-mixing ratio in which light emitted at the selected primary emission wavelengths and their respective luminances is combined in order for the combined output signal to arrive at the standard illuminant point.

58. The method of any of claims 55 to 57, comprising the steps of:
calculating, using the standard-illuminant colour-mixing ratio and the first luminance L₁ at the first primary emission wavelength, the required transmitted luminance L_{T} at the other primary emission wavelengths which will complement the first emission wavelength and its first luminance L₁ and sum to the standard illuminant point; and
calculating a duty cycle for each of the primary emission wavelengths which will result in the required transmitted luminance from the variable-wavelength LED at each primary emission wavelength.

59. The method of any of claims 55 to 58, in which the first, second and third primary emission wavelengths are selected to be red (R), green (G) and blue (B) primary emission wavelengths respectively, and in which the three corresponding driving conditions drive the variable-wavelength LED to emit R, G and B respectively.

60. The method of claim 59, in which the first driving condition drives the variable-wavelength LED to emit a red primary emission wavelength, and in which the first duty cycle has a duration of 100% of the duration of a display subframe, so that the first luminance L₁ is the luminance emitted at the red primary emission wavelength at 100% duty cycle.

61. The method of claim 59 or 60, in which the method comprises the step of reducing the duty cycles of the green and blue driving conditions until the transmitted luminances of the green and blue primary emission wavelengths fulfil the required colour-mixing ratio with the red first transmitted luminance L_{1T}.

62. The method of any of claims 43 to 61, in which the variable-wavelength LED is a device pixel, and in which the method is a method of calibrating the display for field-sequential driving of the variable-wavelength LED pixel to emit a plurality of primary emission wavelengths in sequential subframes of a display frame.

63. The method of any of claims 43 to 62, in which the variable-wavelength LED is a pixel of the display device, and in which the method is a method of calibrating a field-sequential display device comprising a variable-wavelength LED pixel.

64. The method of any of claims 43 to 61, in which the display device comprises a subpixellated display in which pixels of the display each comprise two or more subpixels, the variable-wavelength LED being a first subpixel of a plurality of subpixels of a device pixel.

65. The method of any of claims 43 to 64, in which the method comprises a step of storing the calibrated duty cycles for the sets of primary emission wavelengths.

66. The method of any of claims 43 to 65, in which the method comprises the steps of programming a display controller with the calibrated duty cycles for the sets of primary emission wavelengths.

67. The method of any of claims 43 to 66, in which the method comprises the step of calibrating the transmitted luminances of the complementary primary emission wavelengths by measuring the transmitted luminance which is transmitted by the absorptive colour filter and passes out of the outlet of the display device as the variable-wavelength LED pixel is driven across its emission wavelength range.

68. A method of driving a display device comprising a variable-wavelength LED, the variable-wavelength LED being a pixel of the device, or one of a plurality of subpixels of a device pixel, and an absorptive colour filter, the absorptive colour filter being positioned between the variable-wavelength LED and an outlet of the display device, such that light emitted by the variable-wavelength LED passes through the absorptive colour filter before passing out of the outlet of the display device,
the method comprising the steps of:
driving the variable-wavelength LED, or a second LED subpixel, with a first driving condition for a first duty cycle to emit a first emission wavelength λ₁, with a first luminance L₁, in which the first emission wavelength is transmitted out of the absorptive colour filter with a first transmitted luminance L_{1T};
driving the variable-wavelength LED, with a second driving condition for a second duty cycle to emit a second emission wavelength λ₂, with a second luminance L₂, the second emission wavelength being shorter than the first emission wavelength;
in which the absorptive colour filter is configured to attenuate the second luminance L₂ of the second emission wavelength so that the second emission wavelength is transmitted out of the absorptive colour filter with a second transmitted luminance L_{2T}, wherein L_{2T}<L₂; and
controlling the duration of the first and second duty cycles so that an output signal emitted from the outlet of the display device has an output chromaticity and an output luminance L_{O}.

69. The method of claim 68, in which the display device is a subpixellated display, in which the variable-wavelength LED is a first variable-wavelength subpixel, and in which the method comprises the steps of driving a second LED subpixel to emit light at the first emission wavelength, and driving the first variable-wavelength subpixel to emit light at the second emission wavelength.

70. The method of claim 68, in which the variable-wavelength LED is a pixel of the device, and wherein the method comprises the steps of driving the variable-wavelength LED with a first driving condition for a first duty cycle to emit a first emission wavelength λ₁ of the device, and driving the variable-wavelength LED with a second driving condition for a second duty cycle to emit a second emission wavelength λ₂.

71. The method of any of claims 68 to 70, comprising the step of driving the variable-wavelength LED with a third driving condition for a third duty cycle to emit a third emission wavelength λ₃ of the device, with a third luminance L₃, the third emission wavelength being shorter than the first emission wavelength,
in which the absorptive colour filter is configured to attenuate the third luminance L₃ so that the third emission wavelength is transmitted out of the absorptive colour filter with a third transmitted luminance L_{3T}, wherein L_{3T}<L₃,
and in which the method comprises the step of controlling the duration of the first, second and third duty cycles so that an output signal emitted from the outlet of the display device has an output chromaticity and an output luminance L_{O}.

72. The method of claim 71, comprising the step of controlling the duration of the third duty cycle so that the first, second and third emission wavelengths and the first, second and third transmitted luminances L_{1T}, L_{2T}, L_{3T} are complementary and sum to a standard illuminant point.

73. The method of claim 71 or 72, in which the second emission wavelength and the third emission wavelength are shorter than the first emission wavelength.

74. The method of any of claims 68 to 73, in which the respective duty cycles of the driving conditions are calibrated duty cycles obtained from the method of any of claims 43 to 67.

75. The method of any of claims 68 to 74, in which the method is a field-sequential driving method for driving a display device comprising a variable-wavelength LED pixel, comprising the steps of:
driving the variable-wavelength LED pixel to emit light at three or more primary emission wavelengths in response to respective driving conditions in sequential subframes of the display frame.
